(19) United States
(12) Patent Application Publication
(10) Pub. No.: US 2026/0296954 A1
(43) Pub. Date: Oct. 1, 2026

(54) GLASS-CERAMIC SUBSTRATES HAVING IMPROVED MECHANICAL DURABILITY AND MICROELECTRONIC ARTICLES INCLUDING SAME

(71) Applicant: CORNING INCORPORATED, CORNING, NY (US)

(72) Inventors: Eduardo Augusto Barros de Moraes, Horseheads, NY (US); Jason Roy Grenier, Horseheads, NY (US); Mandakini Kanungo, Ithaca, NY (US); Alvin Wen Mao, Painted Post, NY (US); Chukwudi Azubuike Okoro, Painted Post, NY (US); Robert Anthony Schaut, Horseheads, NY (US); Stanislav Sikulskyi, Corning, NY (US); Rajesh Vaddi, Horseheads, NY (US)

(21) Appl. No.: 19/575,241

(22) Filed: Mar. 23, 2026

Related U.S. Application Data
(60) Provisional application No. 63/777,821, filed on Mar. 26, 2025.
(60) Provisional application No. 63/906,651, filed on Oct. 28, 2025.

(51) Int. Cl. C03C 4/10; C03C 10/00; C03C 21/00

(52) U.S. Cl. CPC C03C 4/10; C03C 10/00; C03C 10/0009; C03C 10/0027; C03C 21/002

(57) ABSTRACT

A glass-ceramic substrate includes a crystalline phase, a residual glass phase, greater than or equal to 50 mol % and less than or equal to 80 mol % SiO₂, greater than or equal to 1 mol % and less than or equal to 20 mol % Al₂O₃, greater than or equal to 0 mol % and less than or equal to 10 mol % TiO₂, greater than or equal to 0 mol % and less than or equal to 5 mol % ZrO₂, and greater than or equal to 0 mol % and less than or equal to 3 mol % P₂O₅. TiO₂+ZrO₂+P₂O₅ is greater than 0 mol % and less than or equal to 13 mol %. The glass-ceramic substrate comprises a fracture toughness greater than or equal to 0.75 MPa·m^{1/2}.

This application claims the benefit of priority to U.S. Provisional Patent Application Ser. No. 63/906,651 filed on Oct. 28, 2025 and to U.S. Provisional Patent Application Ser. No. 63/777,821 filed on Mar. 26, 2025, the contents of which are relied upon and incorporated herein by reference in their entirety.

### FIELD

The present specification relates to glass-ceramic substrates and, in particular, to glass-ceramic substrates having improved mechanical durability and microelectronic articles including the glass-ceramic substrates.

### TECHNICAL BACKGROUND

Glass-based substrates are widely used in microelectronic articles due to attributes such as low dielectric constant, high rigidity, and panel size capability. The glass-based substrates used in microelectronics may include through glass vias (TGVs) and/or redistribution layers (RDLs). Glass core substrates are useful in reducing thickness, improving flatness, warp resistance, and electrical performance over other interposers, such as polymer interposers. Redistribution layers include an overlay of multiple layers of metal and dielectric materials. However, due to the brittle nature of glass, glass fracturing and warpage may occur in glass-based substrates having TGVs and/or RDLs due to the increased stresses applied to the glass-based substrate.

Accordingly, a need exists for glass-based substrates that have improved mechanical performance.

### SUMMARY

According to a first aspect A1, a glass-ceramic substrate comprises: a crystalline phase; a residual glass phase; greater than or equal to 50 mol % and less than or equal to 80 mol % SiO₂; greater than or equal to 1 mol % and less than or equal to 20 mol % Al₂O₃; greater than or equal to 0 mol % and less than or equal to 10 mol % TiO₂; greater than or equal to 0 mol % and less than or equal to 5 mol % ZrO₂; and greater than or equal to 0 mol % and less than or equal to 3 mol % P₂O₅; wherein TiO₂+ZrO₂+P₂O₅ is greater than 0 mol % and less than or equal to 13 mol %, and wherein the glass-ceramic substrate comprises a fracture toughness greater than or equal to 0.75 MPa·m^{1/2}.

A second aspect A2 includes the glass-ceramic substrate of the first aspect A1, wherein grains of the crystalline phase comprise a grain size greater than or equal to 20 nanometers and less than or equal to 10 microns.

A third aspect A3 includes the glass-ceramic substrate of either the first or second aspects A1-A2, wherein the crystalline phase comprises β-quartz, spodumene, β-spodumene, spinel, lithium disilicate, lithium metasilicate, calcium metasilicate, magnesium metasilicate, wollastonite, pseudowollastonite, enstatite, protoenstatite, clinoenstatite, zircon, beta-eucryptite, cordierite, mica, fluororicherite, or combinations thereof.

A fourth aspect A4 includes the glass-ceramic substrate of any one of the previous aspects A1-A3, wherein TiO₂+ZrO₂+P₂O₅ is greater than or equal to 0.5 mol % and less than or equal to 9 mol %.

A fifth aspect A5 includes the glass-ceramic substrate of any one of the previous aspects A1-A4, wherein the glass-ceramic substrate comprises greater than or equal to 1 mol % and less than or equal to 6 mol % TiO₂.

A sixth aspect A6 includes the glass-ceramic substrate of any one of the previous aspects A1-A5, wherein the glass-ceramic substrate comprises greater than or equal to 0.5 mol % and less than or equal to 3 mol % ZrO₂.

A seventh aspect A7 includes the glass-ceramic substrate of any one of the previous aspects A1-A6, wherein the glass-ceramic substrate comprises greater than 0 mol % and less than or equal to 30 mol % Li₂O.

An eighth aspect A8 includes the glass-ceramic substrate of any one of the previous aspects A1-A7, wherein the glass-ceramic substrate comprises greater than 0 mol % and less than or equal to 5 mol % Na₂O.

A ninth aspect A9 includes the glass-ceramic substrate of any one of the previous aspects A1-A8, wherein Li₂O+Na₂O is greater than 0 mol % and less than or equal to 35 mol %.

A tenth aspect A10 includes the glass-ceramic substrate of any one of the previous aspects A1-A9, wherein the glass-ceramic substrate comprises greater than 0 mol % and less than or equal to 1 mol % K₂O.

An eleventh aspect A11 includes the glass-ceramic substrate of any one of the previous aspects A1-A10, wherein the glass-ceramic substrate comprises greater than 0 mol % and less than or equal to 5 mol % B₂O₃.

A twelfth aspect A12 includes the glass-ceramic substrate of any one of the previous aspects A1-A11, wherein the glass-ceramic substrate comprises greater than or equal to 0 mol % and less than or equal to 1.5 mol % P₂O₅.

A thirteenth aspect A13 includes the glass-ceramic substrate of any one of the previous aspects A1-A12, wherein the glass-ceramic substrate comprises greater than 0 mol % and less than or equal to 20 mol % MgO.

A fourteenth aspect A14 includes the glass-ceramic substrate of any one of the previous aspects A1-A13, wherein the glass-ceramic substrate comprises: greater than or equal to 0 mol % and less than or equal to 10 mol % ZnO; greater than or equal to 0 mol % and less than or equal to 3 mol % CaO; greater than or equal to 0 mol % and less than or equal to 3 mol % SrO; and greater than or equal to 0 mol % and less than or equal to 3 mol % BaO.

A fifteenth aspect A15 includes the glass-ceramic substrate of any one of the previous aspects A1-A14, wherein the glass-ceramic substrate comprises greater than or equal to 11 mol % and less than or equal to 15 mol % Al₂O₃.

A sixteenth aspect A16 includes the glass-ceramic substrate of any one of the previous aspects A1-A15, wherein the glass-ceramic substrate comprises greater than or equal to 62 mol % and less than or equal to 74 mol % SiO₂.

A seventeenth aspect A17 includes the glass-ceramic substrate of any one of the previous aspects A1-A16, wherein the glass-ceramic substrate comprises greater than 0 mol % and less than or equal to 1 mol % SnO₂.

An eighteenth aspect A18 includes the glass-ceramic substrate of any one of the previous aspects A1-A17, wherein the glass-ceramic substrate comprises greater than 0 mol % and less than or equal to 1 mol % As₂O₅.

A nineteenth aspect A19 includes the glass-ceramic substrate of any one of the previous aspects A1-A18, wherein the fracture toughness of the glass-ceramic substrate is greater than or equal to 0.80 MPa·m^{1/2}.

A twentieth aspect A20 includes the glass-ceramic substrate of any one of the previous aspects A1-A19, wherein the glass-ceramic substrate comprises an elastic modulus greater than or equal to 82 GPa.

A twenty-first aspect A21 includes the glass-ceramic substrate of any one of the previous aspects A1-A20, wherein the glass-ceramic substrate comprises a coefficient of thermal expansion greater than or equal to 10×10⁻⁷/K and less than or equal to 100×10⁻⁷/K.

A twenty-second aspect A22 includes the glass-ceramic substrate of any one of the previous aspects A1-A21, wherein the glass-ceramic substrate comprises a high temperature coefficient of thermal expansion greater than or equal to 100×10⁻⁷/K and less than or equal to 650×10⁻⁷/K.

A twenty-third aspect A23 includes the glass-ceramic substrate of any one of the previous aspects A1-A22, wherein the glass-ceramic substrate comprises an axial transmittance greater than or equal to 80% and less than or equal to 100% for at least one wavelength within a wavelength range of greater than or equal to 200 nm and less than or equal to 3000 nm.

A twenty-fourth aspect A24 includes the glass-ceramic substrate of any one of the previous aspects A1-A23, wherein the glass-ceramic substrate comprises an axial transmittance greater than or equal to 80% and less than or equal to 100% for at least one wavelength within a wavelength range greater than or equal to 200 nm and less than or equal to 2100 nm.

A twenty-fifth aspect A25, includes the glass-ceramic substrate of any one of the previous aspects A1-A24, wherein the glass-ceramic substrate comprises an axial transmittance greater than or equal to 10% and less than or equal to 80% for at least one wavelength within a wavelength range greater than or equal to 200 nm and less than or equal to 3000 nm.

A twenty-sixth aspect, includes the glass-ceramic substrate of any one of the previous aspects A1-A25, wherein the glass-ceramic substrate comprises an axial transmittance greater than or equal to 10% and less than or equal to 80% for at least one wavelength within a wavelength range greater than or equal to 200 nm and less than or equal to 2100 nm.

A twenty-seventh aspect, includes the glass-ceramic substrate of any one of the aspects A23-A26, wherein the axial transmittance is measured at an article thickness of 0.5 mm.

A twenty-eighth aspect A28 includes the glass-ceramic substrate of any one of the previous aspects A1-A27, wherein the glass-ceramic substrate comprises an internal transmittance greater than or equal to 90% and less than or equal to 100%, as measured at a wavelength range greater than or equal to 400 nm and less than or equal to 1064 nm at an article thickness of 0.5 mm.

A twenty-ninth aspect A29 includes the glass-ceramic substrate of any one of the previous aspects A1-A28, wherein the glass-ceramic substrate comprises an internal transmittance greater than or equal to 10% and less than or equal to 90%, as measured at a wavelength range greater than or equal to 400 nm and less than or equal to 1064 nm at an article thickness of 0.5 mm.

A thirtieth aspect A30 includes the glass-ceramic substrate of any one of the previous aspects A1-A29, wherein the glass-ceramic substrate comprises an internal transmittance greater than or equal to 0% and less than or equal to 10%, as measured at a wavelength range greater than or equal to 400 nm and less than or equal to 1064 nm at an article thickness of 0.5 mm.

A thirty-first aspect A31 includes the glass-ceramic substrate of any one of the previous aspects A21-A30, wherein the glass-ceramic substrate comprises a through glass via.

A thirty-second aspect A31 includes a microelectronic article comprising the glass-ceramic substrate of the thirtieth aspect A30.

A thirty-third aspect A33 includes the microelectronic article of the thirty-second aspect A32, wherein the through glass via is metallized.

A thirty-fourth aspect A34 includes the microelectronic article of either one of the thirty-second or thirty-third aspects A32-A33, further comprising at least one redistribution layer disposed on the glass-ceramic substrate.

A thirty-fifth aspect A35 includes the microelectronic article of the thirty-fourth aspect A34, wherein the at least one redistribution layer comprises a metal material and a dielectric material.

A thirty-sixth aspect A36 includes the microelectronic article of the thirty-fifth aspect A35, wherein the metal material is patterned.

A thirty-seventh aspect A37 includes the microelectronic article of either one of the thirty-fifth or thirty-sixth aspects A35-A36, wherein the metal material comprises copper, aluminum, silver, tin, aluminum-copper, gold, titanium, titanium-tungsten, tantalum, tantalum-nitrogen, chromium, nickel, palladium or combinations thereof.

A thirty-eighth aspect A38 includes the microelectronic article of any one of the thirty-fourth through thirty-seventh aspects A34-A37, wherein the at least one redistribution layer comprises an adhesion promoter.

A thirty-ninth aspect A39 includes the microelectronic article of any one of the thirty-fourth through thirty-seventh aspects A34-A37, wherein the dielectric material comprises polyimide, polybenzoxazoles, polyolefin, polystyrene, epoxy resins, parylene, benzocyclobutene, ring-opened norbornen type polymers, or combinations thereof.

A fortieth aspect A40 includes the microelectronic article of any one of the thirty-fourth through thirty-ninth aspects A34-A39, wherein the at least one redistribution layer comprises greater than or equal to 2 layers and less than or equal to 10 layers of the metal material.

A forty-first aspect A41 includes the microelectronic article of the fortieth aspect A40, wherein each of the layers of the metal material comprises a thickness greater than or equal to 0.5 μm and less than or equal to 25 μm.

A forty-second aspect A42 includes the microelectronic article of any one of the thirty-second through forty-first aspects A32-A41, wherein the microelectronic article comprises a warp less than or equal to 320 μm, as measured at an edge of a 50 mm by 50 mm article.

A forty-third aspect A43 includes the microelectronic article of any one of the thirty-second through forty-second aspects A32-A42, wherein the glass-ceramic substrate comprises a thickness greater than or equal to 100 μm and less than or equal to 1500 μm.

A forty-fourth aspect A44 includes the microelectronic article of any one of the thirty-fourth through forty-third aspects A34-A43, wherein the at least one redistribution layer comprises a thickness greater than or equal to 500 nm.

Additional features and advantages of the glass-ceramic substrates and microelectronic articles include same described herein will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 is a microelectronic article, according to one or more embodiments described herein;

FIG. 2 depicts a glass-ceramic substrate with strengthened regions formed therein, according to embodiments disclosed herein;

FIG. 3 is a plot of warp at the center of the edges (y-axis; in microns (μm)) for comparative and example glass-based substrates (x-axis), according to one or more embodiments described herein; and

FIG. 4 is a plot of the ratio of the stress intensity at the tip of edge flaw to the fracture toughness (y-axis) for comparative and example glass-based substrates (x-axis), according to one or more embodiments described herein.

### DETAILED DESCRIPTION

Reference will now be made in detail to various embodiments of glass-ceramic substrates having improved mechanical durability and microelectronic articles including same. According to embodiments, a glass-ceramic substrate includes a crystalline phase, a residual glass phase, greater than or equal to 50 mol % and less than or equal to 80 mol % SiO₂, greater than or equal to 1 mol % and less than or equal to 20 mol % Al₂O₃, greater than or equal to 0 mol % and less than or equal to 10 mol % TiO₂, greater than or equal to 0 mol % and less than or equal to 5 mol % ZrO₂, and greater than or equal to 0 mol % and less than or equal to 3 mol % P₂O₅. TiO₂+ZrO₂+P₂O₅ is greater than 0 mol % and less than or equal to 13 mol %. The glass-ceramic substrate comprises a fracture toughness greater than or equal to 0.75 MPa·m^{1/2}. Various embodiments of glass-ceramic substrates and methods of forming microelectronic articles therefrom will be referred to herein with specific reference to the appended drawings.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

The term “substantially free,” when used to describe the concentration and/or absence of a particular constituent component in a glass-ceramic substrate, means that the constituent component is not intentionally added to the precursor glass composition and the resultant glass-ceramic article. However, the glass-ceramic substrate may contain traces of the constituent component as a contaminant or tramp in amounts of less than 0.1 mol %.

The terms “0 mol %” and “free,” when used to describe the concentration and/or absence of a particular constituent component in a glass-ceramic substrate, means that the constituent component is not present in the glass-ceramic substrate.

In embodiments of the glass-ceramic substrates described herein, the concentrations of constituent components (e.g., SiO₂, Al₂O₃, and the like) are specified in mole percent (mol %) on an oxide basis, unless otherwise specified.

The term “fracture toughness,” as used herein, refers to the K_{Ic} value, and is measured using the double torsion technique described in ASTM STP 559, entitled, “Double Torsion Technique as a Universal Fracture Toughness Test Method,” the contents of which are incorporated herein by reference in their entirety.

Both internal transmittance and axial transmittance data is measured with a Lambda 950 UV/Vis Spectrophotometer manufactured by PerkinElmer Inc. (Waltham, Massachusetts USA).

The term “internal transmittance,” as used herein, refers to transmittance measured by excluding reflection losses at the entrance and exit surfaces of a glass for a given thickness made within a given wavelength range with each whole numbered wavelength weighted equally. In embodiments described herein, the “internal transmittance” is reported over the wavelength range from 200 nm to 3000 nm or from 340 nm to 2100 nm or from 340 nm to 1550 nm or from 400 nm to 1064 nm (inclusive of endpoints).

The term “axial transmittance,” as used herein, refers to transmittance measured within a relatively small acceptance angle along the axis of the incident light. This measurement includes reflection losses at the entrance and exit surfaces of a glass, absorption losses within a glass, and scattering losses that exceed the detector acceptance angle. Measurements are made for a given thickness within a given wavelength range with each whole numbered wavelength weighted equally. In embodiments described herein, the “axial transmittance” is reported over the wavelength range from 200 nm to 3000 nm or from 200 nm to 2100 nm or from 340 nm to 2100 nm or from 340 nm to 1550 nm or from 400 nm to 1064 nm (inclusive of endpoints).

The internal transmittance and/or the axial transmittance of the glass-ceramic substrate described herein may be about 100% or may be lower than 100%. In embodiments, the internal transmittance and/or the axial transmittance is lower than 100% due to different mechanisms, with one potential mechanism of the transmission loss being absorption processes related to electronic transitions within the material of the substrate (radiative or non-radiative decay processes). Another potential mechanism of the transmission loss being refractive index differences between residual glass and crystal phases that results in scattering of the light. In some embodiments, transmittance loss is due to a combination of these and other mechanisms.

The term “transparent,” when used to describe a glass-ceramic substrate described herein, means that the glass-ceramic article has an internal transmittance and/or axial transmittance greater than or equal to 80% or greater than or equal to 90% when measured at normal incidence for light with a wavelength that is at least one wavelength within a wavelength range from 200 nm to 3000 nm or from 200 nm to 2100 nm or from 340 nm to 2100 nm or from 340 nm to 1550 nm or from 400 nm to 1064 nm (inclusive of endpoints). In some embodiments, the internal transmittance and/or axial transmittance is greater than or equal to 80% or greater than or equal to 90% when measured at normal incidence for light with a wavelength that is at least one wavelength within a range from 200 nm to 3000 nm or from or from 200 nm to 2100 nm or form 340 nm to 2100 nm or from 340 nm to 1550 nm or from 400 nm to 1064 nm and at an article thickness of 0.5 mm.

The term “translucent,” when used to describe a glass-ceramic substrate described herein, means that the glass-ceramic substrate has an internal transmittance and/or axial transmittance greater than or equal to 10% and less than 90% or greater than or equal to 10% and less than or equal to 80% when measured at normal incidence for light with a wavelength that is at least one wavelength within a range from 200 nm to 3000 nm or from 200 nm to 2100 nm or from 340 nm to 2100 nm or from 340 nm to 1550 nm or from 400 nm to 1064 nm (inclusive of endpoints). In some embodiments, the internal transmittance and/or axial transmittance is greater than or equal to 10% and less than 80% or greater than or equal to 10% and less than or equal to 90% when measured at normal incidence for light with a wavelength that is at least one wavelength within a range from 200 nm to 3000 nm or from 200 nm to 2100 nm or from 340 nm to 2100 nm or from 340 nm to 1550 nm or from 400 nm to 1064 nm at an article thickness of 0.5 mm.

The term “opaque,” when used to describe a glass-ceramic substrate described herein, means that the glass-ceramic substrate has an internal transmittance and/or axial transmittance less than 10% when measured at normal incidence for light with a wavelength that is at least one wavelength within a range from 200 nm to 3000 nm or from 200 nm to 2100 nm or from 340 nm to 2100 nm or from 340 nm to 1550 nm or from 400 nm to 1064 nm (inclusive of endpoints). In some embodiments, the internal transmittance and/or axial transmittance is less than 10% when measured at normal incidence for light with a wavelength that is at least one wavelength within a range from 200 nm to 3000 nm or from 200 nm to 2100 nm or from 340 nm to 2100 nm or from 340 nm to 1550 nm or from 400 nm to 1064 nm at an article thickness of 0.5 mm.

The term “strain point,” as used herein, refers to the temperature at which the viscosity of the glass composition is 1×10^{14.68} poise as measured in accordance with ASTM C598.

The term “annealing point” or “effective annealing temperature” as used herein, refers to the temperature at which the viscosity of the glass composition is 1×10^{13.18} poise as measured in accordance with ASTM C598.

The term “softening point,” as used herein, refers to the temperature at which the viscosity of the glass composition is 1×10^{7.6} poise. The softening point is measured according to the parallel plate viscosity method which measures the viscosity of inorganic glass from 10⁷ to 10⁹ poise as a function of temperature, similar to ASTM C1351M.

The elastic modulus (also referred to as Young's modulus) of the glass-ceramic substrate, as described herein, is provided in units of gigapascals (GPa) and is measured in accordance with ASTM C623.

The term “linear coefficient of thermal expansion” and “CTE,” as described herein, is measured in accordance with ASTM E228-85 over the temperature range of 25° C. to 300° C. and is expressed in terms of “×10⁻⁷/K.” A “high temperature CTE” refers to the linear coefficient of thermal expansion as measured on a supercooled liquid at a temperature above the glass transformation range, but below the softening point.

Density, as described herein, is measured by the buoyancy method of ASTM C693-93.

The term “grain size,” as used herein, refers to the size of the largest dimension of the grain as measured using scanning electron microscopy as described in M. N. Rahaman, “Ceramic Processing,” CRC Press, 2007, pp. 107.

The term “glass-ceramic substrate,” as used herein, refers to a substrate formed from heat treating a glass substrate to induce nucleation of the crystalline phase. In embodiments, the glass-ceramic substrates have about 1% to about 99% crystallinity.

As discussed herein, glass-based substrates are widely used in microelectronic articles. Glass-ceramic substrates generally have improved fracture toughness relative to articles formed from glass due to the presence of crystalline grains, which impede crack growth, and the relatively high elastic modulus of the glass-ceramic articles. However, silica has a relatively low K_{Ic} fracture toughness of approximately 0.7 MPa·m^{1/2}, which constrains the K_{Ic} fracture toughness of silicate glass-ceramics to be limited to values of about 0.7 MPa·m^{1/2}. An improved fracture toughness (i.e., greater than or equal to 0.75 MPa·m^{1/2}) is desired to reduce the likelihood of crack propagation, particularly in applications involving microelectronic articles.

Disclosed herein are glass-ceramic substrates that mitigate the aforementioned problems. Specifically, the glass-ceramic substrates disclosed herein comprise a through glass via and TiO₂, ZrO₂, and/or P₂O₅. The TiO₂, ZrO₂, and/or P₂O₅ present serve as nucleating agents to help form an interlocking microstructure in the glass substrate upon crystallization, which may aid in improving the fracture toughness of the glass-ceramic substrate. “Interlocking microstructure” means elongated and randomly oriented nanocrystals that are engaged and intertwined with each other. This interlocking structure creates a tortuous path for and impedes crack propagation, which results in a glass-ceramic substrate having improved fracture toughness for use in microelectronic articles.

The glass-ceramic substrates described herein may be described as aluminosilicate glass-ceramic substrates and comprise SiO₂ and Al₂O₃. In addition to SiO₂ and Al₂O₃, the glass-ceramic substrates described herein further include TiO₂, ZrO₂, and/or P₂O₅ to achieve crystalline phases.

SiO₂ is the primary glass former in the glass-ceramic substrates described herein and may function to stabilize the network structure of the glass-ceramic substrates. The concentration of SiO₂ in the glass-ceramic substrates should be sufficiently high (e.g., greater than or equal to 50 mol %) to provide basic glass forming capability. The concentration of SiO₂ may be limited (e.g., less than or equal to 80 mol %) to control the melting point of the glass-ceramic substrate, as the melting temperature of pure SiO₂ or high SiO₂ glasses is undesirably high. Thus, limiting the concentration of SiO₂ may aid in improving the meltability and the formability of the resulting glass-ceramic article.

Accordingly, in embodiments, the glass-ceramic substrate may comprise greater than or equal to 50 mol % and less than or equal to 80 mol % SiO₂. In embodiments, the glass-ceramic substrate may comprise greater than or equal to 62 mol % and less than or equal to 80 mol % SiO₂. In embodiments, the concentration of SiO₂ in the glass-ceramic substrate may be greater than or equal to 50 mol %, greater than or equal to 54 mol %, greater than or equal to 58 mol %, greater than or equal to 62 mol %, greater than or equal to 66 mol %, or even greater than or equal to 68 mol %. In embodiments, the concentration of SiO₂ in the glass-ceramic substrate may be less than or equal to 80 mol %, less than or equal to 78 mol %, less than or equal to 76 mol %, less than or equal to 74 mol %, or even less than or equal to 72 mol %. In embodiments, the concentration of SiO₂ in the glass-ceramic substrate may be may be greater than or equal to 50 mol % and less than or equal to 80 mol %, greater than or equal to 50 mol % and less than or equal to 78 mol %, greater than or equal to 50 mol % and less than or equal to 76 mol %, greater than or equal to 50 mol % and less than or equal to 74 mol %, greater than or equal to 50 mol % and less than or equal to 72 mol %, greater than or equal to 54 mol % and less than or equal to 80 mol %, greater than or equal to 54 mol % and less than or equal to 78 mol %, greater than or equal to 54 mol % and less than or equal to 76 mol %, greater than or equal to 54 mol % and less than or equal to 74 mol %, greater than or equal to 54 mol % and less than or equal to 72 mol %, greater than or equal to 58 mol % and less than or equal to 80 mol %, greater than or equal to 58 mol % and less than or equal to 78 mol %, greater than or equal to 58 mol % and less than or equal to 76 mol %, greater than or equal to 58 mol % and less than or equal to 74 mol %, greater than or equal to 58 mol % and less than or equal to 72 mol %, greater than or equal to 62 mol % and less than or equal to 80 mol %, greater than or equal to 62 mol % and less than or equal to 78 mol %, greater than or equal to 62 mol % and less than or equal to 76 mol %, greater than or equal to 62 mol % and less than or equal to 74 mol %, greater than or equal to 62 mol % and less than or equal to 72 mol %, greater than or equal to 66 mol % and less than or equal to 80 mol %, greater than or equal to 66 mol % and less than or equal to 78 mol %, greater than or equal to 66 mol % and less than or equal to 76 mol %, greater than or equal to 66 mol % and less than or equal to 74 mol %, or even greater than or equal to 66 mol % and less than or equal to 72 mol %, or any and all sub-ranges formed from any of these endpoints.

Like SiO₂, Al₂O₃ may also stabilize the glass network and additionally provides improved mechanical properties to the glass-ceramic substrate. The amount of Al₂O₃ may also be tailored to control the viscosity of the glass-ceramic substrate. Al₂O₃ may be included such that the glass-ceramic substrate has the desired fracture toughness (e.g., greater than or equal to 0.75 MPa·m^{1/2}). However, if the amount of Al₂O₃ is too high (e.g., greater than 20 mol %), the viscosity of the melt may increase, thereby diminishing the formability of the glass-ceramic substrate.

Accordingly, in embodiments, the glass-ceramic substrate may comprise greater than or equal to 1 mol % and less than or equal to 20 mol % Al₂O₃. In embodiments, the glass-ceramic substrate may comprise greater than or equal to 11 mol % and less than or equal to 15 mol % Al₂O₃. In embodiments, the concentration of Al₂O₃ in the glass-ceramic substrate may be greater than or equal to 1 mol %, greater than or equal to 3 mol %, greater than or equal to 5 mol %, greater than or equal to 7 mol %, greater than or equal to 9 mol %, or even greater than or equal to 11 mol %. In embodiments, the concentration of Al₂O₃ in glass-ceramic substrate may be less than or equal to 20 mol %, less than or equal to 18 mol %, less than or equal to 16 mol %, less than or equal to 14 mol %, less than or equal to 12 mol %, less than or equal to 10 mol %, less than or equal to 8 mol %, or even less than or equal to 6 mol %. In embodiments, the concentration of Al₂O₃ in the glass-ceramic substrate may be greater than or equal to 1 mol % and less than or equal to 20 mol %, greater than or equal to 1 mol % and less than or equal to 18 mol % greater than or equal to 1 mol % and less than or equal to 16 mol %, greater than or equal to 1 mol % and less than or equal to 14 mol %, greater than or equal to 1 mol % and less than or equal to 12 mol %, greater than or equal to 1 mol % and less than or equal to 10 mol %, greater than or equal to 1 mol % and less than or equal to 8 mol %, greater than or equal to 1 mol % and less than or equal to 6 mol %, greater than or equal to 3 mol % and less than or equal to 20 mol %, greater than or equal to 3 mol % and less than or equal to 18 mol % greater than or equal to 3 mol % and less than or equal to 16 mol %, greater than or equal to 3 mol % and less than or equal to 14 mol %, greater than or equal to 3 mol % and less than or equal to 12 mol %, greater than or equal to 3 mol % and less than or equal to 10 mol %, greater than or equal to 3 mol % and less than or equal to 8 mol %, greater than or equal to 3 mol % and less than or equal to 6 mol %, greater than or equal to 5 mol % and less than or equal to 20 mol %, greater than or equal to 5 mol % and less than or equal to 18 mol % greater than or equal to 1 mol % and less than or equal to 16 mol %, greater than or equal to 5 mol % and less than or equal to 14 mol %, greater than or equal to 5 mol % and less than or equal to 12 mol %, greater than or equal to 5 mol % and less than or equal to 10 mol %, greater than or equal to 5 mol % and less than or equal to 8 mol %, greater than or equal to 5 mol % and less than or equal to 6 mol %, greater than or equal to 7 mol % and less than or equal to 20 mol %, greater than or equal to 7 mol % and less than or equal to 18 mol % greater than or equal to 7 mol % and less than or equal to 16 mol %, greater than or equal to 7 mol % and less than or equal to 14 mol %, greater than or equal to 7 mol % and less than or equal to 12 mol %, greater than or equal to 7 mol % and less than or equal to 10 mol %, greater than or equal to 7 mol % and less than or equal to 8 mol %, greater than or equal to 9 mol % and less than or equal to 20 mol %, greater than or equal to 9 mol % and less than or equal to 18 mol % greater than or equal to 9 mol % and less than or equal to 16 mol %, greater than or equal to 9 mol % and less than or equal to 14 mol %, greater than or equal to 9 mol % and less than or equal to 12 mol %, greater than or equal to 9 mol % and less than or equal to 10 mol %, greater than or equal to 11 mol % and less than or equal to 20 mol %, greater than or equal to 11 mol % and less than or equal to 18 mol % greater than or equal to 11 mol % and less than or equal to 16 mol %, greater than or equal to 11 mol % and less than or equal to 14 mol %, or even greater than or equal to 11 mol % and less than or equal to 12 mol %, or any and all sub-ranges formed from any of these endpoints.

The glass-ceramic substrate described herein may comprise TiO₂, ZrO₂, and/or P₂O₅ to achieve crystalline phases. TiO₂, ZrO₂, and/or P₂O₅ serves as a nucleating agent to produce bulk nucleation of the crystalline phase in the glass, thereby transforming the glass substrate into a glass-ceramic substrate. There must be at least some TiO₂, ZrO₂, and/or P₂O₅ present in the glass-ceramic substrate (i.e., greater than 0 mol %) to achieve crystallization. The total concentration of TiO₂, ZrO₂, and/or P₂O₅ may be limited (e.g., less than or equal to 13 mol %) to reduce devitrification during forming and to reduce the liquidus temperature.

In embodiments, the sum of TiO₂, ZrO₂, and P₂O₅ (i.e., TiO₂ (mol %)+ZrO₂ (mol %)+P₂O₅ (mol %)) may be greater than 0 mol % and less than or equal to 13 mol %. In embodiments, TiO₂+ZrO₂+P₂O₅ may be greater than 0.5 mol % and less than or equal to 13 mol %. In embodiments, TiO₂+ZrO₂+P₂O₅ in the glass-ceramic substrate may be greater than 0 mol %, greater than or equal to 0.5 mol %, greater than or equal to 1 mol %, greater than or equal to 1.5 mol %, greater than or equal to 2 mol %, greater than or equal to 2.5 mol %, or even greater than or equal to 3 mol %. In embodiments, TiO₂+ZrO₂+P₂O₅ in the glass-ceramic substrate may be less than or equal to 13 mol %, less than or equal to 11 mol %, less than or equal to 9 mol %, less than or equal to 7 mol %, or even less than or equal to 5 mol %. In embodiments, TiO₂+ZrO₂+P₂O₅ in the glass-ceramic substrate may be greater than 0 mol % and less than or equal to 13 mol %, greater than 0 mol % and less than or equal to 11 mol %, greater than 0 mol % and less than or equal to 9 mol %, greater than 0 mol % and less than or equal to 7 mol %, greater than 0 mol % and less than or equal to 5 mol %, greater than or equal to 0.5 mol % and less than or equal to 13 mol %, greater than or equal to 0.5 mol % and less than or equal to 11 mol %, greater than or equal to 0.5 mol % and less than or equal to 9 mol %, greater than or equal to 0.5 mol % and less than or equal to 7 mol %, greater than or equal to 0.5 mol % and less than or equal to 5 mol %, greater than or equal to 1 mol % and less than or equal to 13 mol %, greater than or equal to 1 mol % and less than or equal to 11 mol %, greater than or equal to 1 mol % and less than or equal to 9 mol %, greater than or equal to 1 mol % and less than or equal to 7 mol %, greater than or equal to 1 mol % and less than or equal to 5 mol %, greater than or equal to 1.5 mol % and less than or equal to 13 mol %, greater than or equal to 1.5 mol % and less than or equal to 11 mol %, greater than or equal to 1.5 mol % and less than or equal to 9 mol %, greater than or equal to 1.5 mol % and less than or equal to 7 mol %, greater than or equal to 1.5 mol % and less than or equal to 5 mol %, greater than or equal to 2 mol % and less than or equal to 13 mol %, greater than or equal to 2 mol % and less than or equal to 11 mol %, greater than or equal to 2 mol % and less than or equal to 9 mol %, greater than or equal to 2 mol % and less than or equal to 7 mol %, greater than or equal to 2 mol % and less than or equal to 5 mol %, greater than or equal to 2.5 mol % and less than or equal to 13 mol %, greater than or equal to 2.5 mol % and less than or equal to 11 mol %, greater than or equal to 2.5 mol % and less than or equal to 9 mol %, greater than or equal to 2.5 mol % and less than or equal to 7 mol %, greater than or equal to 2.5 mol % and less than or equal to 5 mol %, greater than or equal to 3 mol % and less than or equal to 13 mol %, greater than or equal to 3 mol % and less than or equal to 11 mol %, greater than or equal to 3 mol % and less than or equal to 9 mol %, greater than or equal to 3 mol % and less than or equal to 7 mol %, or even greater than or equal to 3 mol % and less than or equal to 5 mol %, or any and all sub-ranges formed from any of these endpoints.

As described, there must be at least one of TiO₂, ZrO₂, and/or P₂O₅ present in the glass-ceramic substrate to achieve crystallization. It should be understood that TiO₂, ZrO₂, and P₂O₅ may be present individually or in any combination in the glass-ceramic substrate.

Accordingly, in embodiments, the glass-ceramic substrate may comprise greater than or equal to 0 mol % and less than or equal to 10 mol % TiO₂. In embodiments, the glass-ceramic substrate may comprise greater than or equal to 1 mol % and less than or equal to 6 mol % TiO₂. In embodiments, the concentration of TiO₂ in the glass-ceramic substrate may be greater than or equal to 0 mol %, greater than or equal to 0.5 mol %, greater than or equal to 1 mol %, greater than or equal to 1.5 mol %, greater than or equal to 2 mol %, greater than or equal to 2.5 mol %, or even greater than or equal to 3 mol %. In embodiments, the concentration of TiO₂ in the glass-ceramic substrate may be less than or equal to 10 mol %, less than or equal to 9 mol %, less than or equal to 8 mol %, less than or equal to 7 mol %, less than or equal to 6 mol %, or even less than or equal to 5 mol %. In embodiments, the concentration of TiO₂ in the glass-ceramic substrate may be greater than or equal to 0 mol % and less than or equal to 10 mol %, greater than or equal to 0 mol % and less than or equal to 9 mol % greater than or equal to 0 mol % and less than or equal to 8 mol %, greater than or equal to 0 mol % and less than or equal to 7 mol %, greater than or equal to 0 mol % and less than or equal to 6 mol %, greater than or equal to 0 mol % and less than or equal to 5 mol %, greater than or equal to 0.5 mol % and less than or equal to 10 mol %, greater than or equal to 0.5 mol % and less than or equal to 9 mol % greater than or equal to 0.5 mol % and less than or equal to 8 mol %, greater than or equal to 0.5 mol % and less than or equal to 7 mol %, greater than or equal to 0.5 mol % and less than or equal to 6 mol %, greater than or equal to 0.5 mol % and less than or equal to 5 mol %, greater than or equal to 1 mol % and less than or equal to 10 mol %, greater than or equal to 1 mol % and less than or equal to 9 mol % greater than or equal to 1 mol % and less than or equal to 8 mol %, greater than or equal to 1 mol % and less than or equal to 7 mol %, greater than or equal to 1 mol % and less than or equal to 6 mol %, greater than or equal to 1 mol % and less than or equal to 5 mol %, greater than or equal to 1.5 mol % and less than or equal to 10 mol %, greater than or equal to 1.5 mol % and less than or equal to 9 mol % greater than or equal to 1.5 mol % and less than or equal to 8 mol %, greater than or equal to 1.5 mol % and less than or equal to 7 mol %, greater than or equal to 1.5 mol % and less than or equal to 6 mol %, greater than or equal to 1.5 mol % and less than or equal to 5 mol %, greater than or equal to 2 mol % and less than or equal to 10 mol %, greater than or equal to 2 mol % and less than or equal to 9 mol % greater than or equal to 2 mol % and less than or equal to 8 mol %, greater than or equal to 2 mol % and less than or equal to 7 mol %, greater than or equal to 2 mol % and less than or equal to 6 mol %, greater than or equal to 2 mol % and less than or equal to 5 mol %, greater than or equal to 2.5 mol % and less than or equal to 10 mol %, greater than or equal to 2.5 mol % and less than or equal to 9 mol % greater than or equal to 2.5 mol % and less than or equal to 8 mol %, greater than or equal to 2.5 mol % and less than or equal to 7 mol %, greater than or equal to 2.5 mol % and less than or equal to 6 mol %, greater than or equal to 2.5 mol % and less than or equal to 5 mol %, greater than or equal to 3 mol % and less than or equal to 10 mol %, greater than or equal to 3 mol % and less than or equal to 9 mol % greater than or equal to 3 mol % and less than or equal to 8 mol %, greater than or equal to 3 mol % and less than or equal to 7 mol %, greater than or equal to 3 mol % and less than or equal to 6 mol %, greater than or equal to 3 mol % and less than or equal to 5 mol %, or any and all sub-ranges formed from any of these endpoints. In embodiments, the glass-ceramic substrate may be free or substantially free of TiO₂.

In embodiments, the glass-ceramic substrate may comprise greater than or equal to 0 mol % and less than or equal to 5 mol % ZrO₂. In embodiments, the glass-ceramic substrate may comprise greater than or equal to 0.5 mol % and less than or equal to 3 mol % ZrO₂. In embodiments, the concentration of ZrO₂ in the glass-ceramic substrate may be greater than or equal to 0 mol %, greater than or equal to 0.5 mol %, greater than or equal to 1 mol %, greater than or equal to 1.5 mol %. In embodiments, the concentration of ZrO₂ in the glass-ceramic substrate may be less than or equal to 5 mol %, less than or equal to 4.5 mol %, less than or equal to 4 mol %, less than or equal to 3.5 mol %, less than or equal to 3 mol %, less than or equal to 2.5 mol %, less than or equal to 2 mol %, or even less than or equal to 1.5 mol %. In embodiments, the concentration of ZrO₂ in the glass-ceramic substrate may be greater than or equal to 0 mol % and less than or equal to 5 mol %, greater than or equal to 0 mol % and less than or equal to 4 mol % greater than or equal to 0 mol % and less than or equal to 3 mol %, greater than or equal to 0 mol % and less than or equal to 2 mol %, greater than or equal to 0.5 mol % and less than or equal to 5 mol %, greater than or equal to 0.5 mol % and less than or equal to 3 mol %, greater than or equal to 0.5 mol % and less than or equal to 3 mol %, greater than or equal to 0.5 mol % and less than or equal to 2.5 mol %, greater than or equal to 0.5 mol % and less than or equal to 2 mol %, or any and all sub-ranges formed from any of these endpoints. In embodiments, the glass-ceramic substrate may be free or substantially free of ZrO₂.

The glass-ceramic substrates described herein may comprise P₂O₅. In embodiments, the glass-ceramic substrate may comprise greater than or equal to 0 mol % and less than or equal to 3 mol % P₂O₅. In embodiments, the glass-ceramic substrate may comprise greater than or equal to 0 mol % and less than or equal to 1.5 mol % P₂O₅. In embodiments, the concentration of P₂O₅ in the glass-ceramic substrate may be greater than or equal to 0 mol % or even greater than or equal to 0.5 mol %. In embodiments, the concentration of P₂O₅ in the glass-ceramic substrate may be less than or equal to 3 mol %, less than or equal to 2.5 mol %, less than or equal to 2 mol %, less than or equal to 1.5 mol %, or even less than or equal to 1 mol. In embodiments, the concentration of P₂O₅ in the glass-ceramic substrate may be greater than or equal to 0 mol % and less than or equal to 2.5 mol %, greater than or equal to 0 mol % and less than or equal to 2 mol %, greater than or equal to 0 mol % and less than or equal to 1.5 mol %, greater than or equal to 0 mol % and less than or equal to 1 mol %, greater than or equal to 0.5 mol % and less than or equal to 3 mol %, greater than or equal to 0.5 mol % and less than or equal to 2.5 mol %, greater than or equal to 0.5 mol % and less than or equal to 2 mol %, greater than or equal to 0.5 mol % and less than or equal to 1.5 mol %, greater than or equal to 0.5 mol % and less than or equal to 1 mol %, or any and all sub-ranges formed from any of these endpoints. In embodiments, the glass-ceramic substrate may be free or substantially free of P₂O₅.

The glass-ceramic substrate may contain alkali oxides, such as Li₂O and Na₂O, to enable the ion exchangeability of the glass compositions. Li₂O aids in the ion exchangeability of the glass composition and also reduces the softening point of the glass composition thereby increasing the formability of the glass. In embodiments, the glass-ceramic substrate may comprise greater than or equal to 0 mol % and less than or equal to 30 mol % Li₂O. In embodiments, the concentration of Li₂O in the glass-ceramic substrate may be greater than or equal to 0 mol %, greater than or equal to 1 mol %, greater than or equal to 5 mol %, greater than or equal to 10 mol %, greater than or equal to 15 mol %, or even greater than or equal to 20 mol %. In embodiments, the concentration of Li₂O in the glass-ceramic substrate may be less than or equal to 30 mol %, less than or equal to 25 mol %, less than or equal to 20 mol %, or even less than or equal to 10 mol %. In embodiments, the concentration of Li₂O in the glass-ceramic substrate may be greater than or equal to 0 mol % and less than or equal to 30 mol %, greater than or equal to 0 mol % and less than or equal to 25 mol %, greater than or equal to 0 mol % and less than or equal to 20 mol %, greater than or equal to 0 mol % and less than or equal to 15 mol %, greater than or equal to 0 mol % and less than or equal to 10 mol %, greater than or equal to 5 mol % and less than or equal to 30 mol %, greater than or equal to 5 mol % and less than or equal to 25 mol %, greater than or equal to 5 mol % and less than or equal to 20 mol %, greater than or equal to 5 mol % and less than or equal to 15 mol %, greater than or equal to 5 mol % and less than or equal to 10 mol %, greater than or equal to 10 mol % and less than or equal to 30 mol %, greater than or equal to 10 mol % and less than or equal to 25 mol %, greater than or equal to 10 mol % and less than or equal to 20 mol %, greater than or equal to 10 mol % and less than or equal to 15 mol %, greater than or equal to 15 mol % and less than or equal to 30 mol %, greater than or equal to 15 mol % and less than or equal to 25 mol %, greater than or equal to 15 mol % and less than or equal to 20 mol %, greater than or equal to 0 mol % and less than or equal to 30 mol %, or even greater than or equal to 20 mol % and less than or equal to 25 mol %, or any and all sub-ranges formed from any of these endpoints. In embodiments, the glass-ceramic substrate may be free or substantially free of Li₂O.

In addition to aiding in ion exchangeability of the glass composition, Na₂O decreases the melting point and improves formability of the glass composition. However, if too much Na₂O is added to the glass composition, the melting point may be too low. In embodiments, the glass-ceramic substrate may comprise greater than or equal to 0 mol % and less than or equal to 5 mol % Na₂O. In embodiments, the concentration of Na₂O in the glass-ceramic substrate may be greater than or equal to 0 mol %, greater than or equal to 0.2 mol %, greater than or equal to 0.4 mol %, greater than or equal to 0.6 mol %, greater than or equal to 0.8 mol %, or even greater than or equal to 1 mol %. In embodiments, the concentration of Na₂O in the glass-ceramic substrate may be less than or equal to 5 mol %, less than or equal to 4 mol %, less than or equal to 3 mol %, less than or equal to 2 mol % or even less than or equal to 1 mol %. In embodiments, the concentration of Na₂O in the glass-ceramic substrate may be greater than or equal to 0 mol % and less than or equal to 5 mol %, greater than or equal to 0 mol % and less than or equal to 3 mol %, greater than or equal to 0 mol % and less than or equal to 1 mol %, greater than or equal to 0.2 mol % and less than or equal to 5 mol %, greater than or equal to 0.2 mol % and less than or equal to 3 mol %, greater than or equal to 0.2 mol % and less than or equal to 1 mol %, greater than or equal to 0.4 mol % and less than or equal to 5 mol %, greater than or equal to 0.4 mol % and less than or equal to 3 mol %, greater than or equal to 0.4 mol % and less than or equal to 1 mol %, greater than or equal to 0.6 mol % and less than or equal to 5 mol %, greater than or equal to 0.6 mol % and less than or equal to 3 mol %, greater than or equal to 0.6 mol % and less than or equal to 1 mol %, greater than or equal to 0.8 mol % and less than or equal to 5 mol %, greater than or equal to 0.8 mol % and less than or equal to 3 mol %, greater than or equal to 0.8 mol % and less than or equal to 1 mol %, greater than or equal to 1 mol % and less than or equal to 5 mol %, or even greater than or equal to 1 mol % and less than or equal to 3 mol %, or any and all sub-ranges formed from any of these endpoints. In embodiments, the glass-ceramic substrate may be free or substantially free of Na₂O.

In embodiments, the sum of Li₂O and Na₂O (i.e., Li₂O (mol %)+Na₂O (mol %) in the glass-ceramic substrate may be greater than or equal to 0 mol % and less than or equal to 35 mol %. In embodiments, Li₂O+Na₂O in the glass-ceramic substrate may be greater than or equal to 0 mol %, greater than or equal to 0.2 mol %, greater than or equal to 0.5 mol %, greater than or equal to 1 mol %, greater than or equal to 5 mol %, greater than or equal to 10 mol %, greater than or equal to 15 mol %, or even greater than or equal to 20 mol %. In embodiments, Li₂O+Na₂O in the glass-ceramic substrate may be less than or equal to 30 mol %, less than or equal to 25 mol %, less than or equal to 20 mol %, less than or equal to 15 mol %, less than or equal to 10 mol %, less than or equal to 5 mol %, or even less than or equal to 3 mol %. In embodiments, Li₂O+Na₂O in the glass-ceramic substrate may be greater than or equal to 0 mol % and less than or equal to 30 mol %, greater than or equal to 0 mol % and less than or equal to 25 mol %, greater than or equal 0 mol % and less than or equal to 20 mol %, greater than or equal to 0 mol % and less than or equal to 15 mol %, greater than or equal to 0 mol % and less than or equal to 10 mol %, greater than or equal to 0 mol % and less than or equal to 5 mol %, greater than or equal to 0 mol % and less than or equal to 3 mol %, greater than or equal to 0.2 mol % and less than or equal to 30 mol %, greater than or equal to 0.2 mol % and less than or equal to 25 mol %, greater than or equal 0.2 mol % and less than or equal to 20 mol %, greater than or equal to 0.2 mol % and less than or equal to 15 mol %, greater than or equal to 0.2 mol % and less than or equal to 10 mol %, greater than or equal to 0.2 mol % and less than or equal to 5 mol %, greater than or equal to 0.2 mol % and less than or equal to 3 mol %, greater than or equal to 0.5 mol % and less than or equal to 30 mol %, greater than or equal to 0.5 mol % and less than or equal to 25 mol %, greater than or equal 0.5 mol % and less than or equal to 20 mol %, greater than or equal to 0.5 mol % and less than or equal to 15 mol %, greater than or equal to 0.5 mol % and less than or equal to 10 mol %, greater than or equal to 0.5 mol % and less than or equal to 5 mol %, greater than or equal to 0.5 mol % and less than or equal to 3 mol %, greater than or equal to 1 mol % and less than or equal to 30 mol %, greater than or equal to 1 mol % and less than or equal to 25 mol %, greater than or equal 1 mol % and less than or equal to 20 mol %, greater than or equal to 1 mol % and less than or equal to 15 mol %, greater than or equal to 1 mol % and less than or equal to 10 mol %, greater than or equal to 1 mol % and less than or equal to 5 mol %, greater than or equal to 1 mol % and less than or equal to 3 mol %, greater than or equal to 5 mol % and less than or equal to 30 mol %, greater than or equal to 5 mol % and less than or equal to 25 mol %, greater than or equal 5 mol % and less than or equal to 20 mol %, greater than or equal to 5 mol % and less than or equal to 15 mol %, greater than or equal to 5 mol % and less than or equal to 10 mol %, greater than or equal to 10 mol % and less than or equal to 30 mol %, greater than or equal to 10 mol % and less than or equal to 25 mol %, greater than or equal 10 mol % and less than or equal to 20 mol %, greater than or equal to 10 mol % and less than or equal to 15 mol %, greater than or equal to 15 mol % and less than or equal to 30 mol %, greater than or equal to 15 mol % and less than or equal to 25 mol %, greater than or equal 15 mol % and less than or equal to 20 mol %, greater than or equal to 20 mol % and less than or equal to 30 mol %, or even greater than or equal to 20 mol % and less than or equal to 25 mol %, or any and all sub-ranges formed from any of these endpoints.

The glass-ceramic substrate may further comprise K₂O. K₂O promotes ion exchange, increases the depth of compression, and decreases the melting point to improve formability of the resulting glass-ceramic substrate. However, adding K₂O may cause the surface compressive stress and melting point to be too low. In embodiments, the glass-ceramic substrate may comprise greater than or equal to 0 mol % and less than or equal to 1 mol % K₂O. In embodiments, the concentration of K₂O in the glass-ceramic substrate may be greater than or equal to 0 mol %, or greater than or equal to 0.1 mol. %, or greater than or equal to 0.2 mol %, or greater than or equal to 0.3 mol %, or greater than or equal to 0.4 mol %, or greater than or equal to 0.5 mol %, or greater than or equal to 0.6 mol %, or greater than or equal to 0.7 mol %, or greater than or equal to 0.8 mol %, or even greater than or equal to 0.9 mol %. In embodiments, the concentration of K₂O in the glass-ceramic substrate may be less than or equal to 1 mol %, less than or equal to 0.8 mol %, less than or equal to 0.6 mol %, less than or equal to 0.4 mol %, or even less than or equal to 0.2 mol %. In embodiments, the concentration of K₂O in the glass-ceramic substrate may be greater than or equal to 0 mol % and less than or equal to 1 mol %, greater than or equal to 0 mol % and less than or equal to 0.8 mol %, greater than or equal to 0 mol % and less than or equal to 0.6 mol %, greater than or equal to 0 mol % and less than or equal to 0.4 mol %, greater than or equal to 0 mol % and less than or equal to 0.2 mol %, greater than or equal to 0.1 mol % and less than or equal to 1 mol %, greater than or equal to 0.1 mol % and less than or equal to 0.8 mol %, greater than or equal to 0.1 mol % and less than or equal to 0.6 mol %, greater than or equal to 0.1 mol % and less than or equal to 0.4 mol %, or even greater than or equal to 0.1 mol % and less than or equal to 0.2 mol %, or any and all sub-ranges formed from any of these endpoints. In embodiments, the glass-ceramic substrate may be free or substantially free of K₂O.

The glass-ceramic substrate described herein may further comprise B₂O₃. B₂O₃ decreases the melting temperature of the glass-ceramic substrate. In addition, B₂O₃ may also improve the damage resistance of the glass-ceramic substrate. B₂O₃ may be included in the glass-ceramic substrate to improve the formability and increase the fracture toughness of the glass-ceramic substrate. In embodiments, the glass-ceramic substrate may comprise greater than or equal to 0 mol % and less than or equal to 5 mol % B₂O₃. In embodiments, the concentration of B₂O₃ in the glass-ceramic substrate may be greater than or equal to 0 mol %, greater than or equal to 0.5 mol %, or even greater than or equal to 1 mol %. In embodiments, the concentration of B₂O₃ in the glass-ceramic substrate may be less than or equal to 5 mol %, less than or equal to 4 mol %, less than or equal to 3 mol %, or even less than or equal to 2 mol %. In embodiments, the concentration of B₂O₃ in the glass-ceramic substrate may be greater than or equal to 0 mol % and less than or equal to 5 mol %, greater than or equal to 0 mol % and less than or equal to 4 mol %, greater than or equal to 0 mol % and less than or equal to 3 mol %, greater than or equal to 0 mol % and less than or equal to 2 mol %, greater than or equal to 0.5 mol % and less than or equal to 5 mol %, greater than or equal to 0.5 mol % and less than or equal to 3 mol %, greater than or equal to 0.5 mol % and less than or equal to 3 mol %, greater than or equal to 0.5 mol % and less than or equal to 2 mol %, greater than or equal to 1 mol % and less than or equal to 5 mol %, greater than or equal to 1 mol % and less than or equal to 4 mol %, greater than or equal to 1 mol % and less than or equal to 3 mol %, greater than or equal to 1 mol % and less than or equal to 2 mol %, or any and all sub-ranges formed from any of these endpoints. In embodiments, the glass-ceramic substrate may be free or substantially free of B₂O₃.

The glass-ceramic substrate described herein may further comprise MgO. MgO lowers the viscosity of the glass-ceramic substrate, which enhances the formability, the strain point, and the Young's modulus, and may improve the ion exchangeability. However, when too much MgO is added to the glass-ceramic substrate, the diffusivity of sodium and potassium ions in the glass-ceramic substrate decreases which, in turn, adversely impacts the ion exchange performance (i.e., the ability to ion-exchange) of the glass-ceramic. In embodiments, the glass-ceramic substrate may comprise greater than or equal to 0 mol % and less than or equal to 20 mol % MgO. In embodiments, the concentration of MgO in the glass-ceramic substrate may be greater than or equal to 0 mol %, greater than or equal to 1 mol %, greater than or equal to 2 mol %, greater than or equal to 4 mol %, greater than or equal to 6 mol %, greater than or equal to 8 mol %, greater than or equal to 10 mol %, or even greater than or equal to 12 mol %. In embodiments, the concentration of MgO in the glass-ceramic substrate may be less than or equal to 20 mol %, less than or equal to 15 mol %, less than or equal to 10 mol %, or even less than or equal to 5 mol %. In embodiments, the concentration of MgO in the glass-ceramic substrate may be greater than or equal to 0 mol % and less than or equal to 20 mol %, greater than or equal to 0 mol % and less than or equal to 15 mol % greater than or equal to 0 mol % and less than or equal to 10 mol %, greater than or equal to 0 mol % and less than or equal to 5 mol %, greater than or equal to 1 mol % and less than or equal to 20 mol %, greater than or equal to 1 mol % and less than or equal to 15 mol %, greater than or equal to 1 mol % and less than or equal to 10 mol %, greater than or equal to 1 mol % and less than or equal to 5 mol %, greater than or equal to 2 mol % and less than or equal to 20 mol %, greater than or equal to 2 mol % and less than or equal to 15 mol %, greater than or equal to 2 mol % and less than or equal to 10 mol %, greater than or equal to 2 mol % and less than or equal to 5 mol %, greater than or equal to 4 mol % and less than or equal to 20 mol %, greater than or equal to 4 mol % and less than or equal to 15 mol %, greater than or equal to 4 mol % and less than or equal to 10 mol %, greater than or equal to 4 mol % and less than or equal to 5 mol %, greater than or equal to 6 mol % and less than or equal to 20 mol %, greater than or equal to 6 mol % and less than or equal to 15 mol %, greater than or equal to 6 mol % and less than or equal to 10 mol %, greater than or equal to 8 mol % and less than or equal to 20 mol %, greater than or equal to 8 mol % and less than or equal to 15 mol %, greater than or equal to 8 mol % and less than or equal to 10 mol %, greater than or equal to 10 mol % and less than or equal to 20 mol %, greater than or equal to 10 mol % and less than or equal to 15 mol %, greater than or equal to 12 mol % and less than or equal to 20 mol %, or even greater than or equal to 12 mol % and less than or equal to 15 mol %, or any and all sub-ranges formed from any of these endpoints. In embodiments, the glass-ceramic substrate may be free or substantially free of MgO.

The glass-ceramic substrate described herein may further comprise divalent cation oxides other than MgO, such as ZnO, CaO, SrO, and/or BaO. In embodiments, the glass-ceramic substrate may comprise greater than or equal to 0 mol % and less than or equal to 10 mol % ZnO. In embodiments, the concentration of ZnO in the glass-ceramic substrate may be greater than or equal to 0 mol %, greater than or equal to 1 mol %, greater than or equal to 3 mol %, greater than or equal to 5 mol %, or even greater than or equal to 7 mol %. In embodiments, the concentration of ZnO in the glass-ceramic substrate may be less than or equal to 10 mol %, less than or equal to 9 mol %, less than or equal to 7 mol %, less than or equal to 5 mol %, or even less than or equal to 3 mol %. In embodiments, the concentration of ZnO in the glass-ceramic substrate may be greater than or equal to 0 mol % and less than or equal to 10 mol %, greater than or equal to 0 mol % and less than or equal to 9 mol %, greater than or equal to 0 mol % and less than or equal to 7 mol %, greater than or equal to 0 mol % and less than or equal to 5 mol %, greater than or equal to 0 mol % and less than or equal to 3 mol %, greater than or equal to 1 mol % and less than or equal to 10 mol %, greater than or equal to 1 mol % and less than or equal to 9 mol %, greater than or equal to 1 mol % and less than or equal to 7 mol %, greater than or equal to 1 mol % and less than or equal to 5 mol %, greater than or equal to 1 mol % and less than or equal to 3 mol %, greater than or equal to 3 mol % and less than or equal to 10 mol %, greater than or equal to 3 mol % and less than or equal to 9 mol %, greater than or equal to 3 mol % and less than or equal to 7 mol %, greater than or equal to 3 mol % and less than or equal to 5 mol %, greater than or equal to 5 mol % and less than or equal to 10 mol %, greater than or equal to 5 mol % and less than or equal to 9 mol %, greater than or equal to 5 mol % and less than or equal to 7 mol %, greater than or equal to 7 mol % and less than or equal to 10 mol %, or even greater than or equal to 7 mol % and less than or equal to 9 mol %, or any and all sub-ranges formed from any of these endpoints. In embodiments, the glass-ceramic substrate may be free or substantially free of ZnO.

In embodiments, the glass-ceramic substrate may comprise greater than or equal to 0 mol % and less than or equal to 3 mol % CaO. In embodiments, the concentration of CaO in the glass-ceramic substrate may be greater than or equal to 0 mol % or even greater than or equal to 0.5 mol %. In embodiments, the concentration of CaO in the glass-ceramic substrate may be less than or equal to 3 mol %, less than or equal to 2 mol %, or even less than or equal to 1 mol %. In embodiments, the concentration of CaO in the glass-ceramic substrate may be greater than or equal to 0 mol % and less than or equal to 3 mol %, greater than or equal to 0 mol % and less than or equal to 2 mol %, greater than or equal to 0 mol % and less than or equal to 1 mol %, greater than or equal to 0.5 mol % and less than or equal to 3 mol %, greater than or equal to 0.5 mol % and less than or equal to 2 mol %, or even greater than or equal to 0.5 mol % and less than or equal to 1 mol %, or any and all sub-ranges formed from any of these endpoints. In embodiments, the glass-ceramic substrate may be free or substantially free of CaO.

In embodiments, the glass-ceramic substrate may comprise greater than or equal to 0 mol % and less than or equal to 3 mol % SrO. In embodiments, the concentration of SrO in the glass-ceramic substrate may be greater than or equal to 0 mol % or even greater than or equal to 0.5 mol %. In embodiments, the concentration of SrO in the glass-ceramic substrate may be less than or equal to 3 mol %, less than or equal to 2 mol %, or even less than or equal to 1 mol %. In embodiments, the concentration of SrO in the glass-ceramic substrate may be greater than or equal to 0 mol % and less than or equal to 3 mol %, greater than or equal to 0 mol % and less than or equal to 2 mol %, greater than or equal to 0 mol % and less than or equal to 1 mol %, greater than or equal to 0.5 mol % and less than or equal to 3 mol %, greater than or equal to 0.5 mol % and less than or equal to 2 mol %, or even greater than or equal to 0.5 mol % and less than or equal to 1 mol %, or any and all sub-ranges formed from any of these endpoints. In embodiments, the glass-ceramic substrate may be free or substantially free of SrO.

In embodiments, the glass-ceramic substrate may comprise greater than or equal to 0 mol % and less than or equal to 3 mol % BaO. In embodiments, the concentration of BaO in the glass-ceramic substrate may be greater than or equal to 0 mol % or even greater than or equal to 0.5 mol %. In embodiments, the concentration of BaO in the glass-ceramic substrate may be less than or equal to 3 mol %, less than or equal to 2 mol %, or even less than or equal to 1 mol %. In embodiments, the concentration of BaO in the glass-ceramic substrate may be greater than or equal to 0 mol % and less than or equal to 3 mol %, greater than or equal to 0 mol % and less than or equal to 2 mol %, greater than or equal to 0 mol % and less than or equal to 1 mol %, greater than or equal to 0.5 mol % and less than or equal to 3 mol %, greater than or equal to 0.5 mol % and less than or equal to 2 mol %, or even greater than or equal to 0.5 mol % and less than or equal to 1 mol %, or any and all sub-ranges formed from any of these endpoints. In embodiments, the glass-ceramic substrate may be free or substantially free of BaO.

In embodiments, the glass-ceramic substrate described herein may further include one or more fining agents. In embodiments, the fining agents may include, for example, SnO₂. In embodiments, the glass-ceramic substrate may comprise greater than 0 mol % and less than or equal to 1 mol % SnO₂. In embodiments, the concentration of SnO₂ in the glass-ceramic substrate may be greater than or equal to 0 mol %, or even greater than or equal to 0.1 mol %. In embodiments, the concentration of SnO₂ in the glass-ceramic substrate may be less than or equal to 1 mol %, less than or equal to 0.5 mol %, or even less than or equal to 0.3 mol %. In embodiments, the concentration of SnO₂ in the glass-ceramic substrate may be greater than or equal to 0 mol % and less than or equal to 1 mol %, greater than or equal to 0 mol % and less than or equal to 0.5 mol %, greater than or equal to 0 mol % and less than or equal to 0.3 mol %, greater than or equal to 0.1 mol % and less than or equal to 1 mol %, greater than or equal to 0.1 mol % and less than or equal to 0.5 mol %, or even greater than or equal to 0.1 mol % and less than or equal to 0.3 mol %, or any and all sub-ranges formed from any of these endpoints. In embodiments, the glass-ceramic substrate may be substantially free of SnO₂.

In embodiments, the glass-ceramic substrate described herein may be formed according to a ceram schedule. The ceram schedule may include heat treating a glass substrate formed from a precursor glass composition in an oven at one or more preselected temperatures for one or more preselected times to induce glass homogenization and crystallization (i.e., nucleation and growth) of one or more crystalline phases (e.g., having one or more compositions, amounts, morphologies, sizes or size distributions, etc.). In embodiments, the heat treatment may include (i) heating a precursor glass substrate in an oven at a rate greater than or equal to 1° C./min and less than or equal to 10° C./min to a nucleation temperature; (ii) maintaining the glass substrate at the nucleation temperature in the oven for time greater than or equal to 0.1 hour and less than or equal to 4 hours to produce a nucleated crystallizable glass; (iii) heating the nucleated crystallizable glass substrate in the oven at a rate greater than or equal to 1° C./min and less than or equal to 10° C./min to a crystallization temperature; (iv) maintaining the nucleated crystallizable glass substrate at the crystallization temperature in the oven for a time greater than or equal to 0.1 hour and less than or equal to 12 hours to produce the glass-ceramic substrate; and (ν) cooling the glass-ceramic substrate to room temperature.

In embodiments, the nucleation temperature is above the annealing and strain temperatures of the precursor glass substrate. For silicate glasses, the nucleation temperature may generally be greater than 600° C. and less than or equal to 800° C., although higher nucleation temperatures are contemplated. The crystallization temperature may be greater than the nucleation temperature. In embodiments, the crystallization temperature may be greater than the nucleation temperature and less than the liquidus temperature of the precursor glass substrate. In embodiments, the crystallization temperature may generally be greater than or equal to 700° C. and less than or equal to 1100° C.

As utilized herein, the heating rates, nucleation temperature, and crystallization temperature refer to the heating rate and temperature of the oven in which the precursor glass substrate or glass substrate is being heat treated.

In addition to the precursor glass compositions, temperature-temporal profiles of heat treatment steps of heating to the crystallization temperature and maintaining the temperature at the crystallization temperature are judiciously prescribed so as to produce one or more of the following desired attributes: crystalline phase(s) of the glass-ceramic substrate, proportions of one or more major crystalline phases and/or one or more minor crystalline phases and residual glass phases, crystal phase assemblages of one or more predominate crystalline phases and/or one or more minor crystalline phases and residual glass phases, and grain sizes or grain size distribution among one or more major crystalline phases and/or one or more minor crystalline phases, which in turn may influence the final integrity, quality, color, and/or opacity of the resulting glass-ceramic substrate.

As described herein, the glass-ceramic substrates described herein include a crystalline phase and a residual glass phase. In embodiments, the crystalline phase may comprise β-quartz, spodumene, β-spodumene, spinel, lithium disilicate, lithium metasilicate, calcium metasilicate, magnesium metasilicate, wollastonite, pseudowollastonite, enstatite, protoenstatite, clinoenstatite, zircon, beta-eucryptite, cordierite, mica, fluororicherite, or combinations thereof. Glass-ceramic substrates offer highly desirable mechanical properties, including high body strength and fracture toughness, due to their microstructures of randomly-oriented interlocked crystals—a crystal structure that forces cracks to propagate through the material via tortuous paths around these crystals.

In embodiments, grains of the crystalline phase may comprise a grain size greater than or equal to 10 nanometers and less than or equal to 10 microns. In embodiments, the grains of the crystalline phase may comprise a grain size greater than or equal to 10 nanometers, greater than or equal to 20 nanometers, greater than or equal to 30 nanometers, greater than or equal to 40 nanometers, greater than or equal to 50 nanometers, greater than or equal to 60 nanometers, greater than or equal to 70 nanometers, greater than or equal to 80 nanometers, greater than or equal to 90 nanometers, greater than or equal to 100 nanometers, greater than or equal to 0.5 microns, greater than or equal to 1 micron, greater than or equal to 2 microns, greater than or equal to 4 microns, greater than or equal to 6 microns, greater than or equal to 8 microns, or greater than or equal to 10 microns. In embodiments, the grains of the crystalline phase may comprise a grain size less than or equal to 10 microns, less than or equal to 8 microns, less than or equal to 6 microns, less than or equal to 4 microns, or less than or equal to 2 microns, or even less than or equal to 1 micron, less than or equal to 0.5 microns, less than or equal to 100 nanometers, less than or equal to 90 nanometers, less than or equal to 80 nanometers, less than or equal to 70 nanometers, less than or equal to 60 nanometers, less than or equal to 50 nanometers, less than or equal to 40 nanometers, less than or equal to 30 nanometers, less than or equal to 20 nanometers, less than or equal to 10 nanometers. In embodiments, grains of the crystalline phase may comprise a grain size greater than or equal to 10 nanometer and less than or equal to 10 microns, greater than or equal to 20 nanometer and less than or equal to 8 microns, greater than or equal to 30 nanometers and less than or equal to 6 microns, greater than or equal to 40 nanometers and less than or equal to 4 microns, greater than or equal to 50 nanometer and less than or equal to 2 microns, greater than or equal to 60 nanometers and less than or equal to 1 micron, greater than or equal to 70 nanometers and less than or equal to 0.5 microns, greater than or equal to 80 nanometers and less than or equal to 100 nanometers, greater than or equal to 90 nanometers and less than or equal to 90 nanometers, greater than or equal to 4 microns and less than or equal to 10 microns, greater than or equal to 4 microns and less than or equal to 8 microns, greater than or equal to 4 microns and less than or equal to 6 microns, greater than or equal to 6 microns and less than or equal to 10 microns, greater than or equal to 6 microns and less than or equal to 8 microns, or even greater than or equal to 8 microns and less than or equal to 10 microns, greater than or equal to 10 nanometers and less than or equal to 80 nanometers, greater than or equal to 20 nanometers and less than or equal to 40 nanometers, or any and all sub-ranges formed from any of these endpoints.

The glass-ceramic substrates described herein may comprise a strain point greater than or equal to 700° C. and less than or equal to 850° C., such as greater than or equal to 725° C. and less than or equal to 825° C., greater than or equal to 750° C. and less than or equal to 800° C., or any and all sub-ranges formed from any of these endpoints.

The glass-ceramic substrates described herein may comprise an annealing point greater than or equal to 700° C. and less than or equal to 950° C., such as greater than or equal to 725° C. and less than or equal to 925° C., greater than or equal to 750° C. and less than or equal to 900° C., or any and all sub-ranges formed from any of these endpoints.

The glass-ceramic substrates described herein may comprise a softening point greater than or equal to 600° C. and less than or equal to 1600° C., such as greater than or equal to 700° C. and less than or equal to 1500° C., greater than or equal to 800° C. and less than or equal to 1400° C., greater than or equal to 900° C. and less than or equal to 1300° C., greater than or equal to 1000° C. and less than or equal to 1200° C., or any and all sub-ranges formed from any of these endpoints. In embodiments, the glass-ceramic substrates described herein may comprise a softening point greater than or equal to 700° C. and less than or equal to 1050° C.

The glass-ceramic substrates described herein may comprise a CTE greater than or equal to 20×10⁻⁷/K and less than or equal to 100×10⁻⁷/K, such as greater than or equal to 30×10⁻⁷/K and less than or equal to 90×10⁻⁷/K, greater than or equal to 40×10⁻⁷/K and less than or equal to 80×10⁻⁷/K, greater than or equal to 50×10⁻⁷/K and less than or equal to 70×10⁻⁷/K, or any and all sub-ranges formed from any of these endpoints. The glass-ceramic substrates described herein may comprise a high temperature CTE greater than or equal to 100×10⁻⁷/K and less than or equal to 650×10⁻⁷/K, such as greater than or equal to 200×10⁻⁷/K and less than or equal to 550×10⁻⁷/K, greater than or equal to 300×10⁻⁷/K and less than or equal to 450×10⁻⁷/K, or any and all sub-ranges formed from any of these endpoints.

The glass-ceramic substrates described herein may comprise an elastic modulus greater than or equal to 80 GPa and less than or equal to 120 GPa, such as greater than or equal to 82 GPa and less than or equal to 118 GPa, greater than or equal to 84 GPa and less than or equal to 116 GPa, greater than or equal to 86 GPa and less than or equal to 114 GPa, or any and all sub-ranges formed from any of these endpoints.

The glass-ceramic substrates described herein may comprise a density greater than or equal to 2.2 g/cm³ and less than or equal to 2.7 g/cm³, such as greater than or equal to 2.2 g/cm³ and less than or equal to 2.65 g/cm³, greater than or equal to 2.25 g/cm³ and less than or equal to 2.6 g/cm³, greater than or equal to 2.3 g/cm³ and less than or equal to 2.6 g/cm³, greater than or equal to 2.35 g/cm³ and less than or equal to 2.6 g/cm³, or any and all sub-ranges formed from any of these endpoints.

As discussed hereinabove, the glass-ceramic substrates described herein may have increased fracture toughness such that the glass-ceramic substrates are more resistant to damage. In embodiments, the glass-ceramic substrates may have a K_{Ic} fracture toughness greater than or equal to 0.75 MPa·m^{1/2}, greater than or equal to 0.8 MPa·m^{1/2}, greater than or equal to 0.85 MPa·m^{1/2}, greater than or equal to 0.9 MPa·m^{1/2}, greater than or equal to 0.95 MPa·m^{1/2}, greater than or equal to 1.0 MPa·m^{1/2}, greater than or equal to 1.05 MPa·m^{1/2}, or even greater than or equal to 1.1 MPa·m^{1/2}, or any and all sub-ranges formed from any of these endpoints.

The glass-ceramic substrates described herein may comprise a through glass via. A “through glass via” is an aperture that extends from a first surface of the glass-ceramic substrate to a second surface of the glass-ceramic substrate. However, in some embodiments, a “through glass via” may extend from the first surface of the glass-ceramic substrate through a depth of the glass-ceramic substrate that is less than the second surface of the glass-ceramic substrate. As described herein, the presence of a through glass via may increase the likelihood of fractures that propagate from the through glass via. However, the glass-ceramic substrates described herein are relatively more resistant to fractures even with such through-glass vias formed therein.

The glass-ceramic substrate may be transparent. The glass-ceramic substrate may comprise an internal transmittance and/or an axial transmittance that is greater than or equal to 80% and less or equal to 100% or that is greater than or equal to 90% and less than or equal to 100% for at least one wavelength within a wavelength range of greater than or equal to 200 nm and less than or equal to 3000 nm or greater than or equal to 200 nm and less than or equal to 2100 nm or greater than or equal to 340 nm and less than or equal to 1550 nm or greater than or equal to 400 nm and less than or equal to 1064 nm or greater than or equal to 400 and less than or equal to 800 nm. In some embodiments, the glass-ceramic comprises the above-disclosed internal transmittance and/or axial transmittance for light over the entire wavelength range of greater than or equal to 200 nm and less than or equal to 3000 nm or greater than or equal to 200 nm and less than or equal to 2100 nm or greater than or equal to 340 nm and less than or equal to 1550 nm or greater than or equal to 400 nm and less than or equal to 1064 nm or greater than or equal to 400 and less than or equal to 800 nm. In embodiments, the glass-ceramic substrate may comprise an internal transmittance and/or an axial transmittance that is greater than or equal to 82% and less than or equal to 100%, greater than or equal to 84% and less than or equal to 100%, greater than or equal to 86% and less than or equal to 100%, greater than or equal to 88% and less than or equal to 100%, greater than or equal to 90% and less than or equal to 100%, 92% and less than or equal to 100%, greater than or equal to 94% and less than or equal to 100%, greater than or equal to 96% and less than or equal to 100%, greater than or equal to 98% and less than or equal to 100%, greater than or equal to 90% and less than or equal to 98%, greater than or equal to 90% and less than or equal to 96%, greater than or equal to 90% and less than or equal to 94%, greater than or equal to 90% and less than or equal to 92%, or any and all sub-ranges formed from any of these endpoints for at least one wavelength within a wavelength range of than or equal to 200 nm and less than or equal to 3000 nm or greater than or equal to 200 nm and less than or equal to 2100 nm or greater than or equal to 340 nm and less than or equal to 1550 nm or greater than or equal to 400 nm and less than or equal to 1064 nm or greater than or equal to 400 nm and less than or equal to 800 nm. In some embodiments, the glass-ceramic comprises the above-disclosed internal transmittance and/or an axial transmittance for light over the entire wavelength range of greater than or equal to 400 nm and less than or equal to 1064 nm or greater than or equal to 200 nm and less than or equal to 3000 nm or greater than or equal to 200 nm and less than or equal to 2100 nm or greater than or equal to 340 nm and less than or equal to 1550 nm or greater than or equal to 400 nm and less than or equal to 1064 nm or greater than or equal to 400 nm and less than or equal to 800 nm. In embodiments disclosed herein, the glass-ceramic substrate comprises the above-disclosed internal transmittance and/or axial transmittance values at an article thickness of 0.5 mm.

The glass-ceramic substrate may be translucent. The glass-ceramic substrate may comprise an internal transmittance and/or axial transmittance that is greater than or equal to 10% and less than or equal to 90% or greater than or equal to 10% and less than or equal to 80% for at least one wavelength within a wavelength range of greater than or equal to 200 nm and less than or equal to 3000 nm or greater than or equal to 200 nm and less than or equal to 2100 nm or greater than or equal to 340 nm and less than or equal to 1550 nm or greater than or equal to 400 nm and less than or equal to 1064 nm or greater than or equal to 400 nm and less than or equal to 800 nm. In some embodiments, the glass-ceramic comprises the above-disclosed internal transmittance and/or axial transmittance for light over the entire wavelength range of greater than or equal to 200 nm and less than or equal to 3000 nm or greater than or equal to 200 nm and less than or equal to 2100 nm or greater than or equal to 340 nm and less than or equal to 1550 nm or greater than or equal to 400 nm and less than or equal to 1064 nm or greater than or equal to 400 and less than or equal to 800 nm. In embodiments, the glass-ceramic substrate may comprise an internal transmittance and/or an axial transmittance that is greater than or equal to 10% and less than or equal to 90%, greater than or equal to 20% and less than or equal to 90%, greater than or equal to 30% and less than or equal to 90%, greater than or equal to 40% and less than or equal to 90%, greater than or equal to 50% and less than or equal to 90%, greater than or equal to 35% and less than or equal to 90%, greater than or equal to 60% and less than or equal to 90%, greater than or equal to 70% and less than or equal to 90%, greater than or equal to 80% and less than or equal to 90%, greater than or equal to 10% and less than or equal to 80%, greater than or equal to 10% and less than or equal to 70%, greater than or equal to 10% and less than or equal to 60%, greater than or equal to 10% and less than or equal to 50%, greater than or equal to 10% and less than or equal to 40%, greater than or equal to 10% and less than or equal to 30%, greater than or equal to 10% and less than or equal to 20%, or any and all sub-ranges formed from any of these endpoints for at least one wavelength within a wavelength range of greater than or equal to 200 nm and less than or equal to 3000 nm or greater than or equal to 200 nm and less than or equal to 2100 nm or greater than or equal to 340 nm and less than or equal to 1550 nm or greater than or equal to 400 nm and less than or equal to 1064 nm or greater than or equal to 400 nm and less than or equal to 800 nm. In some embodiments, the glass-ceramic comprises the above-disclosed internal transmittance and/or axial transmittance for light over the entire wavelength range of greater than or equal to 200 nm and less than or equal to 3000 nm or greater than or equal to 200 nm and less than or equal to 2100 nm or greater than or equal to 340 nm and less than or equal to 1550 nm or greater than or equal to 400 nm and less than or equal to 1064 nm or greater than or equal to 400 and less than or equal to 800 nm. In embodiments disclosed herein, the glass-ceramic substrate comprises the above-disclosed internal transmittance and/or axial transmittance values at an article thickness of 0.5 mm.

The glass-ceramic substrate may be opaque. The glass-ceramic substrate may comprise an internal transmittance and/or an axial transmittance that is greater than or equal to 0% and less than or equal to 10% for at least one wavelength within a wavelength range of greater than or equal to 200 nm and less than or equal to 3000 nm or greater than or equal to 200 nm and less than or equal to 2100 nm or greater than or equal to 340 nm and less than or equal to 1550 nm or greater than or equal to 400 nm and less than or equal to 1064 nm or greater than or equal to 400 nm and less than or equal to 800 nm. In some embodiments, the glass-ceramic comprises the above-disclosed internal transmittance and/or axial transmittance for light over the entire wavelength range of greater than or equal to 200 nm and less than or equal to 3000 nm or greater than or equal to 200 nm and less than or equal to 2100 nm or greater than or equal to 340 nm and less than or equal to 1550 nm or greater than or equal to 400 nm and less than or equal to 1064 nm or greater than or equal to 400 and less than or equal to 800 nm. In embodiments, the glass-ceramic substrate may comprise an internal transmittance and/or an axial transmittance that is greater than or equal to 0% and less than or equal to 10%, greater than or equal to 2% and less than or equal to 10%, greater than or equal to 4% and less than or equal to 10%, greater than or equal to 6% and less than or equal to 10%, greater than or equal to 8% and less than or equal to 10%, greater than or equal to 0% and less than or equal to 8%, greater than or equal to 0% and less than or equal to 6%, greater than or equal to 0% and less than or equal to 4%, greater than or equal to 0% and less than or equal to 2%, or any and all sub-ranges formed from any of these endpoints for at least one wavelength within a wavelength range of greater than or equal to 200 nm and less than or equal to 3000 nm or greater than or equal to 200 nm and less than or equal to 2100 nm or greater than or equal to 340 nm and less than or equal to 1550 nm or greater than or equal to 400 nm and less than or equal to 1064 nm or greater than or equal to 400 nm and less than or equal to 800 nm. In some embodiments, the glass-ceramic comprises the above-disclosed internal transmittance and/or axial transmittance for light over the entire wavelength range of greater than or equal to 200 nm and less than or equal to 3000 nm or greater than or equal to 200 nm and less than or equal to 2100 nm or greater than or equal to 340 nm and less than or equal to 1550 nm or greater than or equal to 400 nm and less than or equal to 1064 nm or greater than or equal to 400 and less than or equal to 800 nm. In embodiments disclosed herein, the glass-ceramic substrate comprises the above-disclosed internal transmittance and/or axial transmittance values at an article thickness of 0.5 mm.

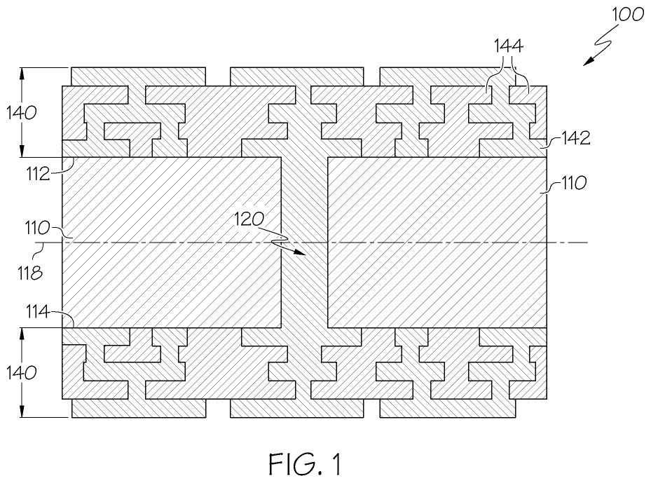

Now turning to FIG. 1, a microelectronic article 100 according to embodiments described herein is depicted. The microelectronic article 100 may comprise a glass-ceramic substrate 110 that comprises a first surface 112 and a second surface 114 opposite the first surface 112. The glass-ceramic substrate 110 may be the glass-ceramic substrate as described herein comprising a through glass via 120. The through glass via 120 may extend from the first surface 112 to the second surface 114 of the glass-ceramic substrate 110. The through glass via 120 may be metallized, such that the through glass via 120 comprises a metal material 142. As used herein, a “metallized through glass via” may refer to a through glass via that comprises the metal material 142. The metal material 142 may be introduced into the through glass via 120. In embodiments, the metal material 142 may completely fill the through glass via 120. In one or more embodiments, the metal material 142 may coat the surfaces of the through glass via 120. The metallized through glass via 120 may serve as an electric connection through the microelectronic article 100.

The glass-ceramic substrate 110 as described herein may be any suitable thickness, which may vary depending on the particular application of the glass-ceramic substrate and/or the microelectronic article 100. The glass-ceramic substrate 110 may comprise a thickness greater than or equal to 100 μm and less than or equal to 1500 μm. In embodiments, the glass-ceramic substrate 110 may comprise a thickness greater than or equal to 100 μm, greater than or equal to 300 μm, greater than or equal to 500 μm, greater than or equal to 700 μm, greater than or equal to 900 μm, greater than or equal to 1100 μm, or even greater than or equal to 1300 μm. In embodiments, the glass-ceramic substrate 110 may comprise a thickness less than or equal to 1500 μm, less than or equal to 1300 μm, less than or equal to 1100 μm, less than or equal to 900 μm, less than or equal to 700 μm, less than or equal to 500 μm, or even less than or equal to 300 μm. In embodiments, the glass-ceramic substrate 110 may comprise a thickness greater than or equal to 200 μm and less than or equal to 1400 μm, greater than or equal to 400 μm and less than or equal to 1200 μm, greater than or equal to 600 μm and less than or equal to 1000 μm, or any and all sub-ranges formed from any of these endpoints.

The microelectronic article 100 may further comprise at least one redistribution layer 140, which may be disposed on the glass-ceramic substrate 110, such as disposed on the first surface 112, the second surface 114, or both. The at least one redistribution layer 140 may be formed (i.e., disposed on the glass-ceramic substrate 110) by at least one cycle of disposing the metal material 142 on the glass-ceramic substrate 110 and disposing a dielectric material 144 at least one of on or between the metal material 142. Disposing the redistribution layer 140 on the glass-ceramic substrate 110 may comprise multiple of these cycles. For example, disposing the at least one redistribution layer 140 on the glass-ceramic substrate 110 may comprise at least two, at least three, at least four, at least five, at least six, at least seven, at least eight, at least nine, or at least ten cycles.

During each of these cycles, the metal material 142 may be chemically etched or patterned resulting in gaps with no metal material 142 present. The dielectric material 144 may be disposed on the patterned metal material 142 such that the dielectric material 144 fills the gaps in the metal material 142 while simultaneously forming on top of the patterned metal material 142. The same process may be employed on the dielectric material 144 of chemical etching or patterning creating gaps in the dielectric material 144, disposing metal material 142 to fill the gaps in the dielectric material 144 with the formation of metal material 142 disposed on the newly formed dielectric material 144. The cycle may be subsequently repeated with the metal material 142 and the dielectric material 144 to build up the desired thickness and makeup of the redistribution layer 140. This process may create the “integrated” redistribution layer 140 wherein the metal material 142 and the dielectric material 144 are joined in an intertwined, or interlocked, manner.

In some embodiments, the microelectronic article 100 may be “double-sided” such that the microelectronic article 100 comprises a first redistribution layer 140 on the first surface 112 of the glass-ceramic substrate 110 and a second redistribution layer 140 on the second surface 114 of the glass-ceramic substrate 110. Additionally, for double-sided microelectronic articles 100, in some embodiments, the redistribution layers 140 may be “symmetric” with respect to the mid-plane 118 of the glass-ceramic substrate 110, wherein each redistribution layer 140 may comprise the metal material 142 and the dielectric material 144 in the same disposal order and/or same etched pattern reflected across the mid-plane 118. In other embodiments (not shown), the redistribution layers 140 may be “asymmetric” with respect to the mid-plane 118. A double-sided and symmetric microelectronic article 100 is shown in FIG. 1. In other embodiments, the microelectronic article 100 may be “single-sided” such that the microelectronic article 100 comprises either a redistribution layer 140 on the first surface 112 or the second surface 114 of the glass-ceramic substrate 110.

The formation of the at least one redistribution layer 140 may cause the buildup of stresses in conventional glass substrates. In conventional single-sided microelectronic articles, the redistribution layers 140 may cause the conventional glass substrates to warp near or at the edges of the glass substrates. The stresses applied to the glass substrates from the redistribution layer(s) 140 may increase the likelihood of fractures in the glass substrates. The fractures may propagate substantially parallel to the mid-plane of the glass substrates. The fractures may propagate from or near the edges of the glass substrates and/or the through a glass via 120 formed in the glass substrates. However, the glass-ceramic substrates 110 described herein may have a relatively high fracture toughness and may be less susceptible to these types of fractures

As discussed above, the at least one redistribution layer 140 of the embodiments disclosed herein may comprise the metal material 142 and the dielectric material 144. The metal material 142 and the dielectric material 144 may be disposed on the glass-ceramic substrate 110 in layers. The metal material 142 and the dielectric material 144 may be integrated, such that the two materials are joined in an intertwined manner. The metal material 142 and the dielectric material 144 may be integrated during the formation process of the at least one redistribution layer 140.

In embodiments, the metal material 142 may be patterned. The metal material 142 may comprise copper, aluminum, silver, tin, aluminum-copper, gold, titanium, titanium-tungsten, tantalum, tantalum-nitrogen, chromium, nickel, palladium or combinations thereof. The dielectric material 144 may comprise polyimide, polybenzoxazoles, polyolefin, polystyrene, epoxy resins, parylene, benzocyclobutene, ring-opened norbornen type polymers, or combinations thereof. The at least one redistribution layer 140 may further comprise an adhesion promoter, such as titanium.

In embodiments, the at least one redistribution layer 140 may comprise greater than or equal to 2 and less than or equal to 10 layers of the metal material 142. For example, the at least one redistribution layer 140 may comprise greater than or equal to 3, greater than or equal to 4, greater than or equal to 5, greater than or equal to 6, greater than or equal to 7, greater than or equal to 8, greater than or equal to 9, less than or equal to 9, less than or equal to 8, less than or equal to 7, less than or equal to 6, less than or equal to 5, less than or equal to 4, or less than or equal to 3 layers of the metal material 142, or any and all sub-ranges formed from any of these endpoints. In embodiments, the at least one redistribution layer 140 may comprise greater than or equal to 2 and less than or equal to 10 layers of dielectric material 144. For example, the at least one redistribution layer 140 may comprise greater than or equal to 3, greater than or equal to 4, greater than or equal to 5, greater than or equal to 6, greater than or equal to 7, greater than or equal to 8, greater than or equal to 9, less than or equal to 9, less than or equal to 8, less than or equal to 7, less than or equal to 6, less than or equal to 5, less than or equal to 4, or less than or equal to 3 layers of the dielectric material 144, or any and all sub-ranges formed from any of these endpoints.

Each of the layers of metal material 142 and each of the layers of dielectric material 144 may comprise a thickness greater than or equal to 0.5 μm and less than or equal to 25 μm. For example, each of the layers of metal material 142 may comprise a thickness greater than or equal to 1 μm, greater than or equal to 2 μm, greater than or equal to 4 μm, greater than or equal to 6 μm, greater than or equal to 8 μm, greater than or equal to 10 μm, greater than or equal to 12 μm, greater than or equal to 14 μm, greater than or equal to 16 μm, greater than or equal to 18 μm, greater than or equal to 20 μm, greater than or equal to 22 μm, greater than or equal to 14 μm and less than or equal to 24 μm, less than or equal to 22 μm, less than or equal to 20 μm, less than or equal to 18 μm, less than or equal to 16 μm, less than or equal to 14 μm, less than or equal to 12 μm, less than or equal to 8 μm, less than or equal to 6 μm, less than or equal to 4 μm, less than or equal to 2 μm, less than or equal to 1 μm, or any and all sub-ranges formed from any of these endpoints. In embodiments, the at least one redistribution layer 140 may have a thickness of greater than or equal to 500 nm. For example, the at least one redistribution layer 140 may have a thickness of greater than or equal to 520 nm, greater than or equal to 540 nm, greater than or equal to 560 nm, greater than or equal to 580 nm, greater than or equal to 600 nm, greater than or equal to 560 nm, greater than or equal to 570 nm, greater than or equal to 580 nm, greater than or equal to 590 nm, or even greater than or equal to 600 nm.

The microelectronic article 100 may comprise a warp less than or equal to 320 μm, as measured at an edge of a 50 mm by 50 mm article. In embodiments, the microelectronic article 100 may comprise a warp less than or equal to 300 μm, less than or equal to 280 μm, less than or equal to 260 μm, less than or equal to 240 μm, less than or equal to 220 μm, less than or equal to 200 μm, or less than or equal to 180 μm, or less than or equal to 160 μm, or less than or equal to 100 μm, as measured at an edge of a 50 mm by 50 mm article, or any range or combination of these endpoints.

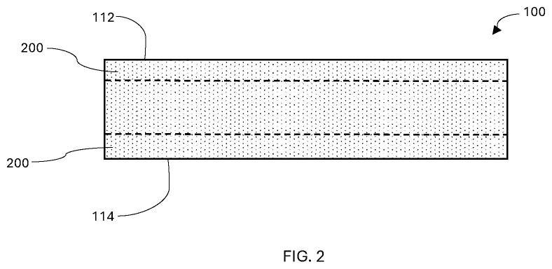

In some embodiments, glass-ceramic substrate 110 may be exposed to a process that induces compressive stress in the substrate. Such a process may comprise for example, a chemical process (such as an ion exchange process), a thermal process (such as a thermal tempering process), and/or a mechanical process. Furthermore, the process may form strengthened regions 200 in glass-ceramic substrate 110, as shown in FIG. 2. In some embodiments, the strengthened regions 200 are formed in glass-based substrate 120 from an ion exchange process. During such an ion exchange process, smaller metal ions in the glass are replaced or “exchanged” with larger metal ions of the same valence within a layer of the glass that is close to an outer surface of the glass. The replacement of the smaller metal ions with the larger metal ions creates a compressive stress within the outer surface regions of the glass, thus producing the strengthened regions 200 in the substrate, as shown in FIG. 2.

In yet some additional embodiments, strengthened regions 200 are also formed along interior surfaces of through-glass vias 120 within glass-ceramic substrate 110. Thus, the process that induces compressive strength in glass-ceramic substrate 110 (e.g., an ion exchange process) to produce strengthened regions 200, as disclosed herein, may be performed either before or after the formation of through-glass vias 120. In some embodiments, the process that induces compressive strength to produce strengthened regions 200 is performed after the formation of through-glass vias 120.

Furthermore, in some embodiments, strengthened regions 200 are also formed along a diced edge surface of glass-ceramic substrate 110. Thus, the process that induces compressive strength in glass-ceramic substrate 110 (e.g., an ion exchange process) to produce strengthened regions 200, as disclosed herein, may be performed either before or after the singulation of glass-ceramic substrate 110. In embodiments, the process that induces compressive strength to produce strengthened regions 200 is performed after the singulation of glass-ceramic substrate 110 to produced a diced edge surface in the substrate.

In embodiments of the ion exchange processes disclosed herein, the smaller metal ions are monovalent alkali metal ions, such as, for example, sodium (Na⁺), potassium (K⁺), or rubidium (Rb⁺) and these smaller monovalent alkali metal ions in glass-ceramic substrate 110 are exchanged with a larger metal ion of a molten salt, such as, for example, potassium nitrate (KNO₃), potassium sulfate (K₂SO₄), potassium chloride (KCl), ), sodium nitrate (NaNO₃), sodium sulfate (Na₂SO₄), sodium carbonate (Na₂CO₃), or sodium chloride (NaCl). In yet some other embodiments, smaller monovalent cations, such as, for example, silver (Ag⁺), Thallium (Tl⁺), or copper (Cu⁺) in glass-ceramic substrate 110 are exchanged for the alkali metal cations. In some embodiments, glass-ceramic substrate 110 is immersed in a bath of the molten salt to exchange the smaller metal ions for the larger metal ions.

During the ion exchange process, glass-ceramic substrate 110 may be immersed in the salt bath for a duration from about 5 minutes to about 40 hours, or about 10 minutes to about 35 hours, or about 20 minutes to about 30 hours, or about 30 minutes to about 25 hours, or about 45 minutes to about 20 hours, or about 1 hour to about 15 hours, or about 2 hours to about 10 hours, or about 5 hours to about 7 hours, or any range encompassing these endpoints. The salt bath may be at a temperature from about 350° C. to about 525° C., or about 375° C. to about 500° C., or about 400° C. to about 475° C., or about 410° C. to about 450° C., or about 425° C. to about 430° C., or any range encompassing these endpoints.

In embodiments, the salt bath comprises an alkali metal. Furthermore, in embodiments, the relatively smaller alkali metal ions (e.g., sodium (Na⁺), potassium (K⁺), or rubidium (Rb⁺)) of glass substrate 20 are exchanged with the relatively larger alkali metal ions in the salt bath, thus producing the strengthened regions 200 in glass-ceramic substrate 110. It is noted that the exchange of the relatively smaller alkali metal ions with the relatively larger alkali metal ions does not take place throughout the bulk of glass-ceramic substrate 110. Instead, the exchange of the alkali metal ions only occurs where the strengthened regions 200 are produced.

In embodiments, the strengthened regions 200 comprise chemically strengthened regions.

In one exemplary embodiment, glass-ceramic substrate 110, with through-glass vias 120 formed therein, is immersed in a KNO₃ salt bath so that Na⁺ ions in the glass are exchanged with K⁻ ions, thus forming strengthened regions 200. In this embodiment, strengthened regions 200 comprise a reduced concentration of Na and a higher concentration of K as compared with the remainder of glass-ceramic substrate 110.

As shown in FIG. 2, strengthened regions 200 may be formed along first surface 112 and/or second surface 114 of glass-ceramic substrate 110. Furthermore, in embodiments in which through glass vias 120 are formed in glass-ceramic substrate 110 before the formation of strengthened regions 200, the strengthened regions 200 may also be formed along interior walls of through-glass vias 120.

Due to the ion exchange processes disclosed herein, strengthened region 200 may have a higher compressive stress than a remainder of glass-ceramic substrate 100. In embodiments, strengthened region 200 may have a surface compressive stress of about 200 MPa or greater, or about 300 MPa or greater, or about 400 MPa or greater, or about 500 MPa or greater, or about 600 MPa or greater, or about 700 MPa or greater, or about 800 MPa or greater, or about 900 MPa or greater, or about 1000 MPa or greater, or any range or combination of ranges formed from these endpoints. In embodiments, the surface compressive stress of strengthened region 200 is in a range from about 200 MPa to about 1000 MPa, or about 300 MPa to about 900 MPa, or about 400 MPa to about 800 MPa, or about 500 MPa to about 700 MPa, or about 600 MPa to about 700 MPa. Surface compressive stress is measured with a surface stress meter (FSM) such as the FSM-6000, as manufactured by Orihara Industrial Co., Ltd. (Japan). Surface compressive stress measurements rely upon the measurement of the stress optical coefficient (SOC), which is related to the birefringence of the glass article. SOC, in turn, is measured according to Procedure C (Glass Disc Method) described in ASTM standard C770-16, entitled “Standard Test Method for Measurement of Glass Stress-Optical Coefficient,” the contents of which are incorporated herein by reference in their entirety. The values reported for surface compressive stress herein refer to the peak surface compressive stress, unless otherwise indicated. In the embodiments disclosed herein, the surface compressive stress is measured using the FSM for the portions of the glass-ceramic substrate 110 that do not comprise through glass vias 120 and then interpolated, based on these measurements, for the surface compressive stress of the portions of glass-ceramic substrate 110 that do comprise through-glass vias 120.

The depth of the strengthened region 200 within the glass-ceramic substrate 110 refers to the depth at which the stress within the glass-ceramic substrate 110 changes from compressive to tensile. Therefore, the strengthened region 200 extends a depth with a bulk of glass-ceramic substrate 110 such that at the end/termination of the strengthened region 200, the stress within glass-ceramic substrate 110 crosses from a compressive stress to a tensile stress and thus exhibits a stress value of zero.

The duration of the salt bath, as described above, may determine the depth of the strengthened region 200 such that a longer salt bath produces relatively larger depth.

### Examples

In order that various embodiments be more readily understood, reference is made to the following examples, which are intended to illustrate various embodiments of the glass-ceramic substrates described herein.

Comparative glass substrate samples C1 and C2 and example glass-ceramic substrate samples E1 to E6 were formulated having the compositions (in mol %) and properties shown in Table 1. The example glass-ceramic substrates were formed according to a ceram schedule described herein.

TABLE 1

| Example | C1 | C2 | E1 | E2 |
|---|---|---|---|---|
| SiO₂ | 67.45 | 67.45 | 72.96 | 69.37 |
| Al₂O₃ | 11.08 | 12.69 | 12.57 | 12.58 |
| B₂O₃ | 9.75 | 3.67 | — | 1.83 |
| P₂O₅ | — | — | — | — |
| Li₂O | — | — | 7.58 | 7.69 |
| Na₂O | 0.02 | 12.30 | 0.21 | 0.31 |
| K₂O | — | 1.37 | 0.14 | — |
| MgO | 2.28 | 2.36 | 1.93 | 2.85 |
| CaO | 8.80 | 0.03 | — | — |
| SrO | 0.51 | — | — | — |
| BaO | — | — | 0.34 | — |
| Fe₂O₃ | 0.01 | — | — | — |
| TiO₂ | — | — | 2.11 | 3.52 |
| ZnO | — | — | 1.27 | 1.73 |
| ZrO₂ | 0.03 | — | 0.89 | — |
| SnO₂ | 0.07 | 0.09 | — | 0.13 |
| As₂O₅ | — | — | — | — |
| TOTAL | 100.00 | 99.96 | 100.00 | 100.01 |
| TiO2 + ZrO2 + P2O5 | 0.03 | 0 | 3.00 | 3.52 |
| Li2O + Na2O | 0.02 | 12.30 | 0.35 | 0.31 |
| Strain Point (° C.) | 672 | 589 | — | 792 |
| Annealing Point (° C.) | 726 | 644 | — | 876 |
| Softening Point (° C.) | — | 922 | — | — |
| CTE (10⁻⁷ K⁻¹) | 32.1 | 74.6 | 50.0 | — |
| High Temp CTE | 146 | 214 | — | — |
| (10⁻⁷ K⁻¹) | | | | |
| Elastic Modulus (GPa) | 74.0 | 69.3 | 86.9 | 85.5 |
| Fracture Toughness | 0.70 | 0.70 | 0.91 | 0.99 |
| (Mpa · m^{1/2}) | | | | |
| Density (g/cm³) | 2.39 | 2.40 | 2.55 | 2.53 |
| Crystalline Phase | — | — | β-quartz | β-spodumene |

| Example | E3 | E4 | E5 | E6 |
|---|---|---|---|---|
| SiO₂ | 68.08 | 65.00 | 70.96 | 70.70 |
| Al₂O₃ | 12.92 | 14.00 | 4.01 | 4.20 |
| B₂O₃ | — | — | — | — |
| P₂O₅ | — | — | 0.77 | 0.90 |
| Li₂O | — | — | 22.78 | 22.10 |
| Na₂O | — | — | 1.49 | — |
| K₂O | — | — | — | — |
| MgO | 4.28 | 14.00 | — | — |
| CaO | — | — | — | — |
| SrO | — | — | — | — |
| BaO | 0.94 | — | — | — |
| Fe₂O₃ | — | — | — | — |
| TiO₂ | 4.32 | 5.00 | — | — |
| ZnO | 7.63 | — | — | — |
| ZrO₂ | 1.68 | 2.00 | — | 2.00 |
| SnO₂ | — | — | — | — |
| As₂O₅ | 0.15 | — | — | — |
| TOTAL | 100.00 | 100.00 | 100.01 | 99.90 |
| TiO₂ + ZrO₂ + P₂O₅ | 6.00 | 7.00 | 0.77 | 2.90 |
| Li₂O + Na₂O | 0 | 0 | 24.27 | 22.10 |
| Strain Point (° C.) | — | — | — | — |
| Annealing Point (° C.) | — | — | 766 | — |
| Softening Point (° C.) | — | — | — | — |
| CTE (10⁻⁷ K⁻¹) | — | — | 65.0 | — |
| High Temp CTE | — | — | — | — |
| (10⁻⁷ K⁻¹) | | | | |
| Elastic Modulus (GPa) | 95 | 110.0 | 98.9 | 102.7 |
| Fracture Toughness | 1.20 | 0.92 | 2.00 | 1.14 |
| (Mpa · m^{1/2}) | | | | |
| Density (g/cm³) | — | — | 2.43 | — |
| Crystalline Phase | Spinel | Spinel | Lithium | Spodumene |
| | | | disilicate | |

As indicated by the example glass-ceramic substrates in Table 1, the glass-ceramic substrates (Examples E1-E6) described herein have improved fracture toughness. Comparative examples C1 and C2 are glass substrates that have a fracture toughness of 0.7 MPa·m^{1/2}. Examples E1-E6 have fracture toughness of greater than 0.9 MPa·m^{1/2}. It is believed that the presence of a crystalline phase in a silica-alumina glass-based substrate along with TiO₂+ZrO₂+P₂O₅ in specific amounts result in the improved fracture toughness shown in Table 1.

### Substrate Warpage and Lateral Fractures

Substrate warpage and lateral fractures were assessed on the glass-ceramic and glass substrates of Table 1.

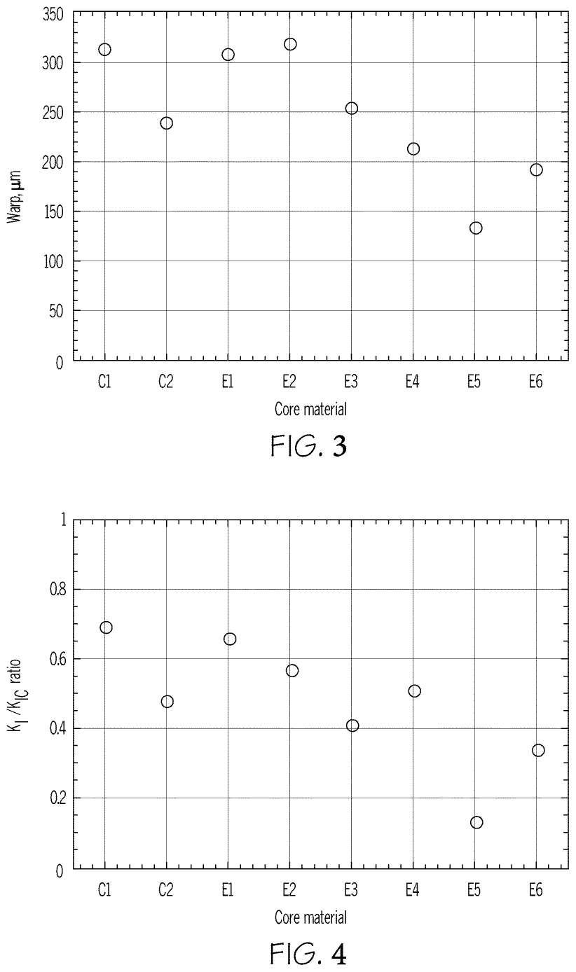

To evaluate substrate warpage, finite element modeling was performed evaluating single-sided glass-ceramic and glass substrates. The glass-ceramic and glass substrates of comparative examples C1 and C2 and of exemplary examples E1-E6 included a redistribution layer on one side of the glass-ceramic and glass substrates. The glass-ceramic and glass substrates had dimensions of 50 mm×50 mm×0.5 mm. The redistribution layer consisted of a titanium adhesion promoter layer (100 nm), a sputtered copper layer (200 nm), and a plated copper layer (15 μm). The glass-ceramic and glass substrates with the redistribution layer thereon were subjected to thermal cycling to determine the glass-ceramic and glass substrate warpage of the samples. The warp at the center of the edges of the glass-ceramic and glass substrates was plotted in FIG. 3.

To evaluate the likelihood of lateral fractures, fracture mechanics modeling was performed evaluating double-sided glass-ceramic and glass substrates. The double-sided glass-ceramic and glass substrates of comparative examples C1 and C2 and of exemplary examples E1-E6 included a redistribution layer on each side of the glass-ceramic and glass substrates. The redistribution layers were identical as in the single-sided glass-ceramic and glass substrates modeling. The glass-ceramic and glass substrates were subjected to thermal cycling to analytically determine the stresses acting on the substrate in the in-plane direction and leading to the lateral fracture of the samples described herein. The in-plane stress was converted into stress intensity at the tip of the edge flaw. The ratio of the stress intensity (K₁) at the tip of edge flaw to the fracture toughness (K_{Ic}) of a given glass-ceramic or glass substrate was evaluated and plotted in FIG. 4 as a metric of lateral fracture likelihood.

As shown in FIG. 3 and FIG. 4, most of the example glass-ceramic substrates E1-E6 with a certain combination of Young's modulus, CTE, and fracture toughness, resulted in reduced likelihood of the lateral fracture at the edge of the double-sided samples and a reduced warp of the single-sided samples relative to the comparative glass substrate samples.

It will be apparent to those skilled in the art that various modifications and variations may be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

What is claimed is:

1. A glass-ceramic substrate, the glass-ceramic substrate comprising:
a crystalline phase;
a residual glass phase;
greater than or equal to 50 mol % and less than or equal to 80 mol % SiO₂;
greater than or equal to 1 mol % and less than or equal to 20 mol % Al₂O₃;
greater than or equal to 0 mol % and less than or equal to 10 mol % TiO₂;
greater than or equal to 0 mol % and less than or equal to 5 mol % ZrO₂; and
greater than or equal to 0 mol % and less than or equal to 3 mol % P₂O₅;
wherein TiO₂+ZrO₂+P₂O₅ is greater than 0 mol % and less than or equal to 13 mol %, and
wherein the glass-ceramic substrate comprises a fracture toughness greater than or equal to 0.75 MPa·m^{1/2}.

2. The glass-ceramic substrate of claim 1, wherein grains of the crystalline phase comprise a grain size greater than or equal to 20 nanometers and less than or equal to 10 microns.

3. The glass-ceramic substrate of claim 1, wherein the crystalline phase comprises β-quartz, spodumene, β-spodumene, spinel, lithium disilicate, lithium metasilicate, calcium metasilicate, magnesium metasilicate, wollastonite, pseudowollastonite, enstatite, protoenstatite, clinoenstatite, zircon, beta-eucryptite, cordierite, mica, fluororicherite, or combinations thereof.

4. The glass-ceramic substrate of claim 1, wherein TiO₂+ZrO₂+P₂O₅ is greater than or equal to 0.5 mol % and less than or equal to 9 mol %.

5. The glass-ceramic substrate of claim 1, wherein the glass-ceramic substrate comprises greater than or equal to 1 mol % and less than or equal to 6 mol % TiO₂.

6. The glass-ceramic substrate of claim 1 wherein the glass-ceramic substrate comprises greater than or equal to 0.5 mol % and less than or equal to 3 mol % ZrO₂.

7. The glass-ceramic substrate of claim 1, wherein Li₂O+Na₂O is greater than 0 mol % and less than or equal to 35 mol %.

8. The glass-ceramic substrate of claim 1 wherein the glass-ceramic substrate comprises greater than 0 mol % and less than or equal to 1 mol % K₂O.

9. The glass-ceramic substrate of claim 1, wherein the glass-ceramic substrate comprises:
greater than or equal to 0 mol % and less than or equal to 10 mol % ZnO;
greater than or equal to 0 mol % and less than or equal to 3 mol % CaO;
greater than or equal to 0 mol % and less than or equal to 3 mol % SrO; and
greater than or equal to 0 mol % and less than or equal to 3 mol % BaO.

10. The glass-ceramic substrate of claim 1, wherein the glass-ceramic substrate comprises greater than or equal to 11 mol % and less than or equal to 15 mol % Al₂O₃.

11. The glass-ceramic substrate of claim 1, wherein the glass-ceramic substrate comprises greater than or equal to 62 mol % and less than or equal to 74 mol % SiO₂.

12. The glass-ceramic substrate of claim 1, wherein the fracture toughness of the glass-ceramic substrate is greater than or equal to 0.80 MPa·m^{1/2}.

13. The glass-ceramic substrate of claim 1, wherein the glass-ceramic substrate comprises an elastic modulus greater than or equal to 82 GPa.

14. The glass-ceramic substrate of claim 1, wherein the glass-ceramic substrate comprises a coefficient of thermal expansion greater than or equal to 10×10⁻⁷/K and less than or equal to 100×10⁻⁷/K.

15. The glass-ceramic substrate of claim 1, wherein the glass-ceramic substrate comprises an axial transmittance greater than or equal to 80% and less than or equal to 100% for at least one wavelength within a wavelength range of greater than or equal to 200 nm and less than or equal to 3000 nm.

16. The glass-ceramic substrate of claim 1, wherein the glass-ceramic substrate comprises an axial transmittance greater than or equal to 80% and less than or equal to 100% for at least one wavelength within a wavelength range of greater than or equal to 200 nm and less than or equal to 2100 nm.

17. The glass-ceramic substrate of claim 1, wherein the glass-ceramic substrate comprises an axial transmittance greater than or equal to 10% and less than or equal to 80% for at least one wavelength within a wavelength range of greater than or equal to 200 nm and less than or equal to 3000 nm.

18. The glass-ceramic substrate of claim 1, wherein the glass-ceramic substrate comprises an axial transmittance greater than or equal to 10% and less than or equal to 80% for at least one wavelength within a wavelength range of greater than or equal to 200 nm and less than or equal to 2100 nm.

19. The glass-ceramic substrate of claim 18, wherein the axial transmittance is measured at an article thickness of 0.5 mm.

20. The glass-ceramic substrate of claim 1, wherein the glass-ceramic substrate comprises an internal transmittance greater than or equal to 90% and less than or equal to 100%, as measured at a wavelength range greater than or equal to 400 nm and less than or equal to 1064 nm at an article thickness of 0.5 mm.

21. The glass-ceramic substrate of claim 1, wherein the glass-ceramic substrate comprises a strengthened region that extends from a surface of the glass-ceramic substrate to a distance within a bulk of the glass-ceramic substrate, the strengthened region having a higher compressive stress than a remainder of the glass-ceramic substrate.

22. The glass-ceramic substrate of claim 21, wherein the strengthened region comprises a surface compressive stress of about 200 MPa or greater.

23. The glass-ceramic substrate of claim 21, wherein the surface of the glass-ceramic substrate is a top surface of the glass-ceramic substrate.

24. The glass-ceramic substrate of claim 21, wherein the glass-ceramic substrate comprises a through glass via and the surface is an interior surface of the through glass via.
